(19) United States
(12) Patent Application Publication
(10) Pub. No.: US 2025/0386591 A1
(43) Pub. Date: Dec. 18, 2025

(54) SEMICONDUCTOR DEVICE INCLUDING MULTI-BRIDGE CHANNEL FIELD EFFECT TRANSISTOR

(71) Applicant: SAMSUNG ELECTRONICS CO., LTD., Suwon-si (KR)

(72) Inventors: Soomin SON, Suwon-si (KR); Jin Bum KIM, Suwon-si (KR); Suk YANG, Suwon-si (KR); Sang Moon LEE, Suwon-si (KR); In Hae ZOH, Suwon-si (KR); Soo Bin HAN, Suwon-si (KR)

(73) Assignee: SAMSUNG ELECTRONICS CO., LTD., Suwon-si (KR)

(21) Appl. No.: 19/020,452

(22) Filed: Jan. 14, 2025

(30) Foreign Application Priority Data
Jun. 17, 2024 (KR) 10-2024-0078008

(51) Int. Cl. H10D 84/83

(52) U.S. Cl. CPC H10D 84/832

(57) ABSTRACT

A semiconductor device includes a substrate, an active pattern extending in a first horizontal direction on the substrate, a first plurality of upper nanosheets stacked on the active pattern to be spaced apart from each other in a vertical direction, a second plurality of upper nanosheets stacked on the active pattern to be spaced apart from each other in the vertical direction, a first gate electrode extending in a second horizontal direction different from the first horizontal direction on the active pattern, a second gate electrode extending in the second horizontal direction on the active pattern, an upper source/drain region between the first plurality of upper nanosheets and the second plurality of upper nanosheets, and a source/drain contact extending to the upper source/drain region and electrically coupled with the upper source/drain region.

### CROSS-REFERENCE TO RELATED APPLICATIONS

This application claims priority to Korean Patent Application No. 10-2024-0078008, filed on Jun. 17, 2024, in the Korean Intellectual Property Office, the disclosure of which is incorporated by reference herein in its entirety.

### BACKGROUND

### 1. Field

The present disclosure relates to a semiconductor device, and more particularly, to a semiconductor device including multi-bridge channel field effect transistor (MBCFET™).

### 2. Description of Related Art

A multi-gate transistor may have been proposed as at least one of possible scaling technologies that may increase density of an integrated circuit device. A multi-gate transistor may refer to a silicon body having a fin and/or nanowire shape that is formed on a substrate and a gate that is formed on a surface of the silicon body.

Such a multi-gate transistor may utilize a three-dimensional (3D) channel, which may facilitate scaling. In addition, the multi-gate transistor may provide for an improved current control capability, even if a gate length of the multi-gate transistor is not increased. Furthermore, a short channel effect (SCE) in which potential of a channel region may be influenced by a drain voltage may be effectively suppressed in the multi-gate transistor.

### SUMMARY

Provided is a semiconductor device having a structure including a plurality of upper nanosheets stacked on a plurality of lower nanosheets, and in which reliability of an electrical connection between a source/drain contact and an upper source/drain region may be improved.

According to an aspect of the disclosure, a semiconductor device includes a substrate, an active pattern extending in a first horizontal direction on the substrate, a first plurality of upper nanosheets stacked on the active pattern to be spaced apart from each other in a vertical direction, a second plurality of upper nanosheets stacked on the active pattern to be spaced apart from each other in the vertical direction, a first gate electrode extending in a second horizontal direction different from the first horizontal direction on the active pattern, a second gate electrode extending in the second horizontal direction on the active pattern, an upper source/drain region between the first plurality of upper nanosheets and the second plurality of upper nanosheets, and a source/drain contact extending inside of the upper source/drain region and electrically coupled with the upper source/drain region. The second plurality of upper nanosheets is spaced apart from the first plurality of upper nanosheets in the first horizontal direction. The first gate electrode at least partially surrounds the first plurality of upper nanosheets. The second gate electrode is spaced apart from the first gate electrode in the first horizontal direction. The second gate electrode at least partially surrounds the second plurality of upper nanosheets. The upper source/drain region includes a first layer in contact with side walls of each of the first plurality of upper nanosheets and the second plurality of upper nanosheets in the first horizontal direction, a second layer below the first layer, and a third layer above the first layer and including a same material as a material of the second layer.

According to an aspect of the present disclosure, a semiconductor device includes a substrate, an active pattern extending in a first horizontal direction on the substrate, a plurality of lower nanosheets stacked on the active pattern to be spaced apart from each other in a vertical direction, a nanosheet separating layer on the plurality of lower nanosheets, a plurality of upper nanosheets on the nanosheet separating layer, a gate electrode extending in a second horizontal direction different from the first horizontal direction on the active pattern, a lower source/drain region on a side of the plurality of lower nanosheets, an upper source/drain region on a side of the plurality of upper nanosheets, and a source/drain contact extending inside of the upper source/drain region and electrically coupled with the upper source/drain region. The gate electrode at least partially surrounds each of the plurality of lower nanosheets, the nanosheet separating layer, and the plurality of upper nanosheets. The upper source/drain region at least partially overlaps the lower source/drain region in the vertical direction. The upper source/drain region includes a first layer in contact with side walls of the plurality of upper nanosheets in the first horizontal direction, a second layer below the first layer, and a third layer above the first layer and including a third material equal to a second material of the second layer. A thickness of the first layer in the vertical direction decreasing toward the source/drain contact.

According to an aspect of the present disclosure, a semiconductor device includes a substrate, an active pattern extending in a first horizontal direction on the substrate, a first plurality of lower nanosheets stacked on the active pattern to be spaced apart from each other in a vertical direction, a second plurality of lower nanosheets stacked on the active pattern to be spaced apart from each other in the vertical direction, a first nanosheet separating layer on the first plurality of lower nanosheets, a second nanosheet separating layer on the second plurality of lower nanosheets, a first plurality of upper nanosheets stacked on the first nanosheet separating layer to be spaced apart from each other in the vertical direction, a second plurality of upper nanosheets stacked on the second nanosheet separating layer to be spaced apart from each other in the vertical direction, a first gate electrode extending in a second horizontal direction different from the first horizontal direction on the active pattern, a second gate electrode extending in the second horizontal direction on the active pattern, a lower source/drain region between the first plurality of lower nanosheets and the second plurality of lower nanosheets, an upper source/drain region between the first plurality of upper nanosheets and the second plurality of upper nanosheets, and a source/drain contact extending inside of the upper source/drain region and electrically coupled with the upper source/drain region. The second plurality of lower nanosheets is spaced apart from the first plurality of lower nanosheets in the first horizontal direction. The second nanosheet separating layer is spaced apart from the first nanosheet separating layer in the first horizontal direction. The second plurality of upper nanosheets is spaced apart from the first plurality of upper nanosheets in the first horizontal direction. The first gate electrode at least partially surrounds each of the first plurality of lower nanosheets, the first nanosheet separating layer, and the first plurality of upper nanosheets. The second gate electrode is spaced apart from the first gate electrode in the first horizontal direction. The second gate electrode at least partially surrounds each of the second plurality of lower nanosheets, the second nanosheet separating layer, and the second plurality of upper nanosheets. The upper source/drain region at least partially overlaps the lower source/drain region in the vertical direction. The upper source/drain region includes a first layer in contact with side walls of the first plurality of upper nanosheets and the second plurality of upper nanosheets in the first horizontal direction, a second layer below the first layer, and a third layer above the first layer and including a same material as a material of the second layer. A thickness of the first layer in the vertical direction decreases toward the source/drain contact. A second crystal density of the second layer is smaller than a first crystal density of the first layer. A third crystal density of the third layer is smaller than the first crystal density of the first layer. A lower surface of the source/drain contact is formed inside the second layer.

However, aspects of the present disclosure are not restricted to the ones set forth herein. The above and other aspects of the present disclosure will become apparent to one of ordinary skill in the art to which the present disclosure pertains by referencing the detailed description of the present disclosure given below.

### BRIEF DESCRIPTION OF THE DRAWINGS

The above and other aspects, features, and advantages of certain embodiments of the present disclosure may be more apparent from the following description taken in conjunction with the accompanying drawings, in which:

FIG. 1 is a layout diagram of a semiconductor device, according to embodiments of the present disclosure;

FIG. 2 is a cross-sectional view taken along line A-A′ of FIG. 1, according to embodiments of the present disclosure;

FIG. 3 is a cross-sectional view taken along line B-B′ of FIG. 1, according to embodiments of the present disclosure;

FIG. 4 is a cross-sectional view taken along line C-C′ of FIG. 1, according to embodiments of the present disclosure;

FIGS. 5 to 28 are intermediate process diagrams of a method for manufacturing the semiconductor device, according to embodiments of the present disclosure;

FIGS. 29 and 30 are cross-sectional views of a semiconductor device, according to embodiments of the present disclosure;

FIGS. 31 and 32 are cross-sectional views of a semiconductor device, according to embodiments of the present disclosure;

FIG. 33 is a cross-sectional view of a semiconductor device, according to embodiments of the present disclosure; and

FIG. 34 is a cross-sectional view of a semiconductor device, according to embodiments of the present disclosure.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

It is to be understood that the specific order or hierarchy of operations in the methods disclosed are an illustration of exemplary approaches. Based upon design preferences, it is understood that the specific order or hierarchy of operations in the methods may be rearranged. Further, some operations may be combined or omitted. The accompanying claims present elements of the various embodiments in a sample order, and are not meant to be limited to the specific order or hierarchy presented.

As used herein, each of the terms “Al₂O₃”, “AlN”, “BaSrTiO”, “BaTiO”, “GaAs”, “GaSb”, “HfAlO”, “HfO₂”, “HfSiO”, “HfZrO”, “InAs”, “InP”, “InSb”, “La₂O₃”, “LaAlO”, “MOC”, “MON”, “NbC”, “NbN”, “Ni—Pt”, “PbScTaO”, “PbTe”, “PbZnNb”, “PbZrTiO”, “SiBCN”, “SiBN”, “SiCN”, “SiGe”, “SiN”, “SiO₂”, “SiOBN”, “SiOC”, “SiOCN”, “SiON”, “SrTiO”, “Ta₂O₅”, “TaAIN”, “TaC”, “TaCN”, “TaN”, “TaSiN”, “TaTiN”, “TiAl”, “TiAlC”, “TiAlCN”, “TiAlN”, “TiC”, “TiN”, “TiO₂”, “TiSiN”, “WC”, “WN”, “Y₂O₃”, “ZrSiO”, and the like may refer to a material made of elements included in each of the terms and is not a chemical formula representing a stoichiometric relationship.

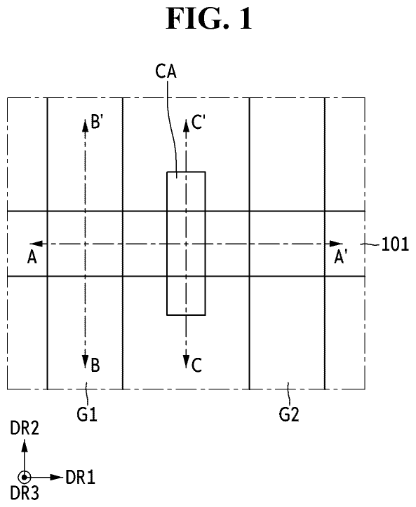

Hereinafter, a semiconductor device, according to embodiments of the present disclosure, is described with reference to FIGS. 1 to 4.

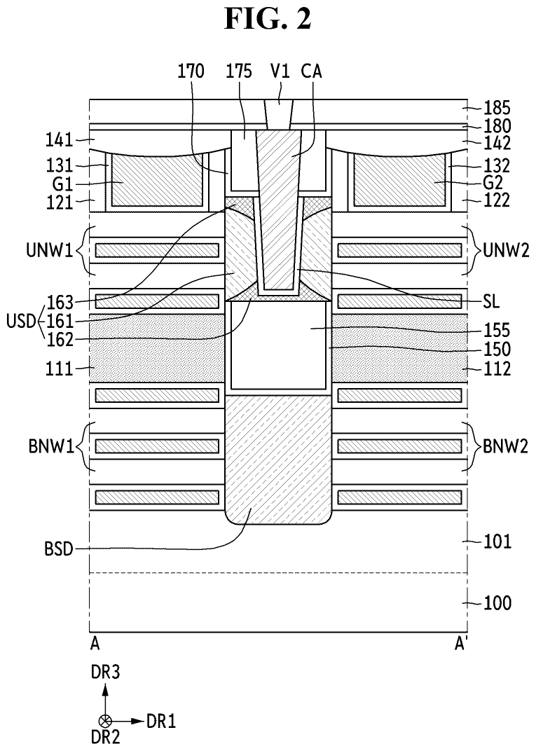

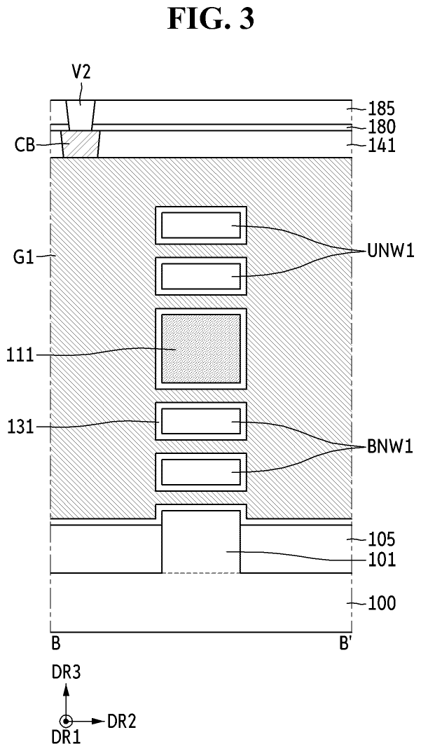

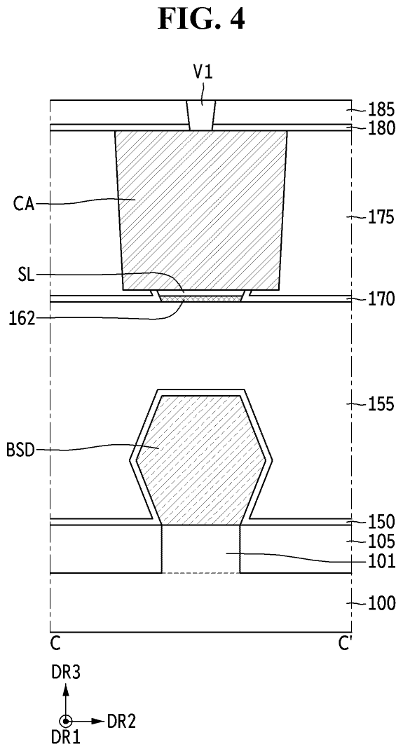

FIG. 1 is a layout diagram of a semiconductor device, according to embodiments of the present disclosure. FIG. 2 is a cross-sectional view taken along line A-A′ of FIG. 1, according to embodiments of the present disclosure. FIG. 3 is a cross-sectional view taken along line B-B′ of FIG. 1, according to embodiments of the present disclosure. FIG. 4 is a cross-sectional view taken along line C-C′ of FIG. 1, according to embodiments of the present disclosure.

Referring to FIGS. 1 to 4, the semiconductor device, according to embodiments of the present disclosure, includes a substrate 100, an active pattern 101, a field insulating layer 105, pluralities of lower nanosheets (e.g., a first plurality of lower nanosheets BNW1 and a second plurality of lower nanosheets BNW2), nanosheet separating layers (e.g. a first nanosheet separating layer 111 and a second nanosheet separating layer 112), pluralities of upper nanosheets (e.g., a first plurality of upper nanosheets UNW1 and a second plurality of upper nanosheets UNW2), gate electrodes (e.g., a first gate electrode G1 and a second gate electrode G2), gate spacers (e.g., first gate spacers 121 and second gate spacers 122), gate insulating layers (e.g., first gate insulating layers 131 and second gate insulating layers 132), capping patterns (e.g., first capping patterns 141 and second capping patterns 142), a lower source/drain region BSD, a first etching stop layer 150, a first interlayer insulating layer 155, an upper source/drain region USD, a second etching stop layer 170, a second interlayer insulating layer 175, a source/drain contact CA, a silicide layer SL, a gate contact CB, a third etching stop layer 180, a third interlayer insulating layer 185, and vias (e.g., first vias V1 and second vias V2).

The substrate 100 may be and/or may include a silicon (Si) substrate or a silicon-on-insulator (SOI). Alternatively or additionally, the substrate 100 may include silicon germanium (SiGe), silicon germanium on insulator (SGOI), indium antimonide (InSb), lead telluride (PbTe), indium arsenide (InAs), indium phosphide (InP), gallium arsenide (GaAs), gallium antimonide (GaSb), or the like. However, the present disclosure is not limited thereto.

Hereinafter, each of a first horizontal direction DR1 and a second horizontal direction DR2 may be referred to as a direction parallel to an upper surface of the substrate 100. The second horizontal direction DR2 may be referred to as a direction different from the first horizontal direction DR1. A vertical direction DR3 may be referred to as a direction perpendicular to each of the first horizontal direction DR1 and the second horizontal direction DR2. That is, the vertical direction DR3 may be referred to as a direction perpendicular to the upper surface of the substrate 100.

The active pattern 101 may protrude from the substrate 100 in the vertical direction DR3. The active pattern 101 may extend in the first horizontal direction DR1. The active pattern 101 may be a part of the substrate 100, and/or may include an epitaxial layer grown from the substrate 100. For example, the active pattern 101 may include the same material as the substrate 100.

The field insulating layer 105 may be disposed on the upper surface of the substrate 100. The field insulating layer 105 may surround a side wall of the active pattern 101. For example, the upper surface of the field insulating layer 105 may be formed to be higher than the upper surface of the active pattern 101. However, the present disclosure is not limited thereto. The field insulating layer 105 may include, for example, an oxide film, a nitride film, an oxynitride film, and/or a combined film thereof.

The first plurality of lower nanosheets BNW1 may be disposed on the active pattern 101. The first plurality of lower nanosheets BNW1 may include a plurality of nanosheets stacked on the active pattern 101 to be spaced apart from each other in the vertical direction DR3. The second plurality of lower nanosheets BNW2 may be disposed on the active pattern 101. The second plurality of lower nanosheets BNW2 may be spaced apart from the first plurality of lower nanosheets BNW1 in the first horizontal direction DR1. The second plurality of lower nanosheets BNW2 may include a plurality of nanosheets stacked on the active pattern 101 to be spaced apart from each other in the vertical direction DR3.

The first plurality of upper nanosheets UNW1 may be disposed on the first plurality of lower nanosheets BNW1. That is, the first plurality of upper nanosheets UNW1 may be disposed on the upper surface of the uppermost nanosheet of the first plurality of lower nanosheets BNW1. For example, the lowermost nanosheet of the first plurality of upper nanosheets UNW1 may be spaced apart from the uppermost nanosheet of the first plurality of lower nanosheets BNW1 in the vertical direction DR3. The first plurality of upper nanosheets UNW1 may include a plurality of nanosheets stacked to be spaced apart from each other in the vertical direction DR3.

The second plurality of upper nanosheets UNW2 may be disposed on the second plurality of lower nanosheets BNW2. That is, the second plurality of upper nanosheets UNW2 may be disposed on the upper surface of the uppermost nanosheet of the second plurality of lower nanosheets BNW2. For example, the lowermost nanosheet of the second plurality of upper nanosheets UNW2 may be spaced apart from the uppermost nanosheet of the second plurality of lower nanosheets BNW2 in the vertical direction DR3. The second plurality of upper nanosheets UNW2 may be spaced apart from the first plurality of upper nanosheets UNW1 in the first horizontal direction DR1. The second plurality of upper nanosheets UNW2 may include a plurality of nanosheets stacked to be spaced apart from each other in the vertical direction DR3.

Although FIGS. 2 and 3 depict the first and second plurality of lower nanosheets BNW1 and BNW2 and the first and second plurality of upper nanosheets UNW1 and UNW2 as including two (2) nanosheets that are stacked in the vertical direction DR3, the present disclosure is not limited thereto. For example, in some embodiments, the first and second plurality of lower nanosheets BNW1 and BNW2 and the first and second plurality of upper nanosheets UNW1 and UNW2 may include three (3) or more nanosheets that are stacked in the vertical direction DR3. Each of the first and second plurality of lower nanosheets BNW1 and BNW2 and the first and second plurality of upper nanosheets UNW1 and UNW2 may include silicon (Si). However, the present disclosure is not limited thereto. In some embodiments, each of the first and second plurality of lower nanosheets BNW1 and BNW2 and the first and second plurality of upper nanosheets UNW1 and UNW2 may include silicon germanium (SiGe).

The first nanosheet separating layer 111 may be disposed between the first plurality of lower nanosheets BNW1 and the first plurality of upper nanosheets UNW1. For example, the first nanosheet separating layer 111 may be disposed between the uppermost nanosheet of the first plurality of lower nanosheets BNW1 and the lowermost nanosheet of the first plurality of upper nanosheets UNW1. As another example, the first nanosheet separating layer 111 may be spaced apart from the uppermost nanosheet of the first plurality of lower nanosheets BNW1 in the vertical direction DR3. In some embodiments, the lowermost nanosheet of the first plurality of upper nanosheets UNW1 may be spaced apart from the first nanosheet separating layer 111 in the vertical direction DR3.

The second nanosheet separating layer 112 may be disposed between the second plurality of lower nanosheets BNW2 and the second plurality of upper nanosheets UNW2. For example, the second nanosheet separating layer 112 may be disposed between the uppermost nanosheet of the second plurality of lower nanosheets BNW2 and the lowermost nanosheet of the second plurality of upper nanosheets UNW2. As another example, the second nanosheet separating layer 112 may be spaced apart from the uppermost nanosheet of the second plurality of lower nanosheets BNW2 in the vertical direction DR3. In some embodiments, the lowermost nanosheet of the second plurality of upper nanosheets UNW2 may be spaced apart from the second nanosheet separating layer 112 in the vertical direction DR3. The second nanosheet separating layer 112 may be spaced apart from the first nanosheet separating layer 111 in the first horizontal direction DR1.

Each of the first and second nanosheet separating layers 111 and 112 may include an insulating material. For example, each of the first and second nanosheet separating layers 111 and 112 may include at least one of silicon nitride (SiN), silicon oxycarbonitride (SiOCN), silicon boron carbonitride (SiBCN), silicon carbonitride (SiCN), silicon oxynitride (SiON), and/or combinations thereof. However, the present disclosure is not limited thereto.

The first gate electrode G1 may extend in the second horizontal direction DR2 on the active pattern 101. For example, the first gate electrode G1 may surround each of the first plurality of lower nanosheets BNW1, the first nanosheet separating layer 111, and the first plurality of upper nanosheets UNW1. However, the present disclosure is not limited thereto. In some embodiments, the first gate electrode G1 may include a first lower gate electrode and a first upper gate electrode that may be spaced apart from each other in the vertical direction DR3. In such a case, the first lower gate electrode may surround the first plurality of lower nanosheets BNW1 and a part of the first nanosheet separating layer 111, and the first upper gate electrode may surround another part of the first nanosheet separating layer 111 and the first plurality of upper nanosheets UNW1.

The second gate electrode G2 may extend in the second horizontal direction DR2 on the active pattern 101. For example, the second gate electrode G2 may be spaced apart from the first gate electrode G1 in the first horizontal direction DR1. As another example, the second gate electrode G2 may surround each of the second plurality of lower nanosheets BNW2, the second nanosheet separating layer 112, and the second plurality of upper nanosheets UNW2. However, the present disclosure is not limited thereto. In some embodiments, the second gate electrode G2 may include a second lower gate electrode and a second upper gate electrode that may be spaced apart from each other in the vertical direction DR3. In such a case, the second lower gate electrode may surround the second plurality of lower nanosheets BNW2 and a part of the second nanosheet separating layer 112, and the second upper gate electrode may surround another part of the second nanosheet separating layer 112 and the second plurality of upper nanosheets UNW1.

Each of the first and second gate electrodes G1 and G2 may include, but not be limited to, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAIN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. Each of the first and second gate electrodes G1 and G2 may include the conductive metal oxide and the conductive metal, oxynitride or the like, and an oxidized form of the aforementioned materials.

A first gate spacer 121 may extend in the second horizontal direction DR2 along both side walls of the first gate electrode G1, on the upper surface of the uppermost nanosheet of the first plurality of upper nanosheets UNW1 and the upper surface of the field insulating layer 105. The second gate spacer 122 may extend in the second horizontal direction DR2 along both side walls of the second gate electrode G2, on the upper surface of the uppermost nanosheet of the second plurality of upper nanosheets UNW2 and the upper surface of the field insulating layer 105. Each of the first and second gate spacers 121 and 122 may include at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof. However, the present disclosure is not limited thereto.

A first gate insulating layer 131 may be disposed between the first gate electrode G1 and the field insulating layer 105. The first gate insulating layer 131 may be disposed between the first gate electrode G1 and the first gate spacer 121. The first gate insulating layer 131 may be disposed between the first gate electrode G1 and the first plurality of lower nanosheets BNW1. The first gate insulating layer 131 may be disposed between the first gate electrode G1 and the first nanosheet separating layer 111. The first gate insulating layer 131 may be disposed between the first gate electrode G1 and the first plurality of upper nanosheets UNW1. The first gate insulating layer 131 may be disposed on both side walls of the first gate electrode G1 in the first horizontal direction DR1.

A second gate insulating layer 132 may be disposed between the second gate electrode G2 and the field insulating layer 105. The second gate insulating layer 132 may be disposed between the second gate electrode G2 and the second gate spacer 122. The second gate insulating layer 132 may be disposed between the second gate electrode G2 and the second plurality of lower nanosheets BNW2. The second gate insulating layer 132 may be disposed between the second gate electrode G2 and the second nanosheet separating layer 112. The second gate insulating layer 132 may be disposed between the second gate electrode G2 and the second plurality of upper nanosheets UNW2. The second gate insulating layer 132 may be disposed on both side walls of the second gate electrode G2 in the first horizontal direction DR1.

Each of the first and second gate insulating layers 131 and 132 may include at least one of silicon oxide (SiO₂), silicon oxynitride (SiON), silicon nitride (SiN), or a high dielectric constant material having a dielectric constant larger than that of silicon oxide (SiO₂). The high dielectric constant material may include, for example, one or more of hafnium oxide (HfO₂), hafnium silicon oxide (HfSiO), hafnium aluminum oxide (HfAlO), lanthanum oxide (La₂O₃), lanthanum aluminum oxide (LaAlO), zirconium oxide (ZrO₂), zirconium silicon oxide (ZrSiO), tantalum oxide (Ta₂O₅), titanium oxide (TiO₂), barium strontium titanium oxide (BaSrTiO), barium titanium oxide (BaTiO), strontium titanium oxide (SrTiO), yttrium oxide (Y₂O₃), aluminum oxide (Al₂O₃), lead scandium tantalum oxide (PbScTaO), and/or lead zinc niobate (PbZnNb).

A semiconductor device, according to embodiments, may include a negative capacitance (NC) field-effect transistor (FET) that may use a negative capacitor. For example, each of the first and second gate insulating layers 131 and 132 may include a ferroelectric material film having ferroelectric properties, and a paraelectric material film having paraelectric properties.

The ferroelectric material film may have a negative capacitance, and the paraelectric material film may have a positive capacitance. For example, if two (2) or more capacitors are connected in series and the capacitance of each capacitor has a positive value, the overall capacitances may decrease from the capacitance of each of the individual capacitors. Alternatively or additionally, if at least one of the capacitances of two (2) or more capacitors connected in series has a negative value, the overall capacitances may be greater than an absolute value of each of the individual capacitances, while having a positive value.

When the ferroelectric material film having the negative capacitance and the paraelectric material film having the positive capacitance are connected in series, the overall capacitance values of the ferroelectric material film and the paraelectric material film connected in series may increase. By the use of the increased overall capacitance value, a transistor including the ferroelectric material film may have a subthreshold swing (SS) below 60 millivolts per decade (mV/decade) at room temperature (e.g., about 20 degrees Celsius (° C.)).

The ferroelectric material film may have ferroelectric properties. The ferroelectric material film may include, but not be limited to, at least one of hafnium oxide (HfO₂), hafnium zirconium oxide (HfZrO), barium strontium titanium oxide (BaSrTiO), barium titanium oxide (BaTiO), and lead zirconium titanium oxide (PbZrTiO). For an example, the hafnium zirconium oxide (HfZrO) may be a material obtained by doping hafnium oxide (HfO₂) with zirconium (Zr). As another example, the hafnium zirconium oxide (HfZrO) may be a compound of hafnium (Hf), zirconium (Zr), and oxygen (O).

The ferroelectric material film may further include a doped dopant. For example, the dopant may include, but not be limited to, at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of dopant included in the ferroelectric material film may vary, depending on which type of ferroelectric material is included in the ferroelectric material film.

When the ferroelectric material film includes hafnium oxide (HfO₂), the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include about 3 atomic percentage (at %) to about 8 at % aluminum (Al). As used herein, a ratio of the dopant may refer to a ratio of aluminum (Al) to the sum of hafnium (Hf) and aluminum (Al).

When the dopant is silicon (Si), the ferroelectric material film may include about 2 at % to about 10 at % silicon (Si). When the dopant is yttrium (Y), the ferroelectric material film may include about 2 at % to about 10 at % yttrium (Y). When the dopant is gadolinium (Gd), the ferroelectric material film may include about 1 at % to about 7 at % gadolinium (Gd). When the dopant is zirconium (Zr), the ferroelectric material film may include about 50 at % to about 80 at % zirconium (Zr).

The paraelectric material film may have the paraelectric properties. The paraelectric material film may include, but not be limited to, at least one of a silicon oxide or a metal oxide having a high dielectric constant. The metal oxide included in the paraelectric material film may include, for example, but not be limited to, at least one of hafnium oxide (HfO₂), zirconium oxide (ZrO₂), or aluminum oxide (Al₂O₃).

The ferroelectric material film and the paraelectric material film may include the same material. The ferroelectric material film may have the ferroelectric properties, however, the paraelectric material film may not have the ferroelectric properties. For example, when the ferroelectric material film and the paraelectric material film include hafnium oxide (HfO₂), a crystal structure of hafnium oxide (HfO₂) included in the ferroelectric material film may be different from a crystal structure of hafnium oxide (HfO₂) included in the paraelectric material film.

The ferroelectric material film may have a thickness having the ferroelectric properties. A thickness of the ferroelectric material film may be, for example, but not limited to, 0.5 to 10 nanometers (nm). Since a critical thickness that exhibits the ferroelectric properties may vary for each ferroelectric material, the thickness of the ferroelectric material film may vary depending on the ferroelectric material.

For example, each of the first and second gate insulating layers 131 and 132 may include one (1) ferroelectric material film. As another example, each of the first and second gate insulating layers 131 and 132 may include a plurality of ferroelectric material films that may be spaced apart from each other. Each of the first and second gate insulating layers 131 and 132 may have a stacked film structure in which the plurality of ferroelectric material films and the plurality of paraelectric material films are alternately stacked.

The lower source/drain region BSD may be disposed between the first plurality of lower nanosheets BNW1 and the second plurality of lower nanosheets BNW2 on the active pattern 101. For example, the lower source/drain region BSD may be in contact with the active pattern 101. For example, the lower source/drain region BSD may be in contact with the side walls of each of the first plurality of lower nanosheets BNW1 and the second plurality of lower nanosheets BNW2 in the first horizontal direction DR1. For example, the upper surface of the lower source/drain region BSD may be formed to be higher than each of the upper surface of the uppermost nanosheet of the first plurality of lower nanosheets BNW1 and the upper surface of the uppermost nanosheet of the second plurality of lower nanosheets BNW2.

For example, the lower source/drain region BSD may be in contact with the each of the first gate insulating layer 131 and the second gate insulating layer 132. However, the present disclosure is not limited thereto. In some embodiments, a first lower internal spacer may be disposed between the lower source/drain region BSD and the first gate insulating layer 131, and a second lower internal spacer may be disposed between the lower source/drain region BSD and the second gate insulating layer 132. For example, each of the first and second lower internal spacers may include at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and/or combinations thereof.

The first etching stop layer 150 may be disposed on the upper surface of the field insulating layer 105, the side walls in the second horizontal direction DR2 and the upper surface of the lower source/drain region BSD. The first etching stop layer 150 may be disposed on the side walls of each of the first and second nanosheet separating layers 111 and 112 in the first horizontal direction DR1. For example, the first etching stop layer 150 may be conformally formed. For example, the first etching stop layer 150 may be in contact with each of the field insulating layer 105, the lower source/drain region BSD, and the first and second nanosheet separating layers 111 and 112. For example, the first etching stop layer 150 may be in contact with each of the first and second gate insulating layers 131 and 132. For example, the first etching stop layer 150 may include, but not be limited to, at least one of aluminum oxide (Al₂O₃), aluminum nitride (AlN), hafnium oxide (HfO₂), zirconium oxide (ZrO₂), silicon oxide (SiO₂), silicon nitride (SiN), silicon oxynitride (SiON), or a low dielectric constant material.

The first interlayer insulating layer 155 may be disposed on the first etching stop layer 150. For example, the first interlayer insulating layer 155 may be in contact with the first etching stop layer 150. The first interlayer insulating layer 155 may cover the lower source/drain region BSD on the field insulating layer 105. For example, the upper surface of the first interlayer insulating layer 155 may be formed to be lower than each of the lower surface of the lowermost nanosheet of the first plurality of upper nanosheets UNW1 and the lower surface of the lowermost nanosheet of the second plurality of upper nanosheets UNW2. As another example, the upper surface of the first interlayer insulating layer 155 may be formed to be higher than the upper surfaces of each of the first and second nanosheet separating layers 111 and 112. However, the present disclosure is not limited thereto.

The first interlayer insulating layer 155 may include, but not be limited to, at least one of silicon oxide (SiO₂), silicon nitride (SiN), silicon oxynitride (SiON), or a low dielectric constant material. The low dielectric constant material may include, for example, fluorinated tetraethyl orthosilicate (FTEOS), hydrogen silsesquioxane (HSQ), bis-benzocyclobutene (BCB), tetramethylorthosilicate (TMOS), octamethylcyclotetrasiloxane (OMCTS), hexamethyldisilazane (HMDS), trimethylsiloxy Borate (TMSB), diacetoxyditertiarybutoxysilane (DADBS), trimethylsilyl phosphate (TMSP), polytetrafluoroethylene (PTFE), tonen silazene (TOSZ), fluoride silicate glass (FSG), polyimide nanofoams such as polypropylene oxide, carbon-doped silicon oxide (CDO), organo silicate glass (OSG), SiLK™, amorphous fluorinated carbon, silica aerogels, silica xerogels, mesoporous silica, and/or combinations thereof. However, the present disclosure is not limited thereto.

The upper source/drain region USD may be disposed between the first plurality of upper nanosheets UNW1 and the second plurality of upper nanosheets UNW2 on the lower source/drain region BSD. For example, the upper source/drain region USD may be spaced apart from the lower source/drain region BSD in the vertical direction DR3. As another example, the lower surface of the upper source/drain region USD may be in contact with each of the first etching stop layer 150 and the first interlayer insulating layer 155. In some embodiments, the upper source/drain region USD may be in contact with the side walls of each of the first and second plurality of upper nanosheets UNW1 and UNW2 in the first horizontal direction DR1.

For example, the lower surface of the upper source/drain region USD may be formed to be lower than each of the lower surface of the lowermost nanosheet of the first plurality of upper nanosheets UNW1 and the lower surface of the lowermost nanosheet of the second plurality of upper nanosheets UNW2. As another example, the upper surface of the upper source/drain region USD may be formed to be higher than each of the upper surface of the uppermost nanosheet of the first plurality of upper nanosheets UNW1 and the upper surface of the uppermost nanosheet of the second plurality of upper nanosheets UNW2.

In some embodiments, the upper source/drain region USD may be in contact with the each of the first gate insulating layer 131 and the second gate insulating layer 132. However, the present disclosure is not limited thereto. For example, a first upper internal spacer may be disposed between the upper source/drain region USD and the first gate insulating layer 131, and a second upper internal spacer may be disposed between the upper source/drain region USD and the second gate insulating layer 132. In some embodiments, each of the first and second upper internal spacers may include, but not be limited to, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and/or combinations thereof.

The second etching stop layer 170 may be disposed on the upper surface of the first interlayer insulating layer 155, a part of the side wall in the second horizontal direction DR2 and the upper surface of the upper source/drain region USD, and side walls of each of the first and second gate spacers 121 and 122 in the second horizontal direction DR2. For example, the second etching stop layer 170 may be conformally formed. As another example, the second etching stop layer 170 may be in contact with each of the first interlayer insulating layer 155, the upper source/drain region USD, and the first and second gate spacers 121 and 122. In some embodiments, the second etching stop layer 170 may include at least one of aluminum oxide (Al₂O₃), aluminum nitride (AlN), hafnium oxide (HfO₂), zirconium oxide (ZrO₂), silicon oxide (SiO₂), silicon nitride (SiN), silicon oxynitride (SiON), a low dielectric constant material, and/or a combination thereof.

The first capping pattern 141 may extend in the second horizontal direction DR2 on each of the first gate spacer 121, the first gate insulating layer 131, and the first gate electrode G1. The second capping pattern 142 may extend in the second horizontal direction DR2 on each of the second gate spacer 122, the second gate insulating layer 132, and the second gate electrode G2. For example, the lower surfaces of each of the first and second capping patterns 141 and 142 may be in contact with the second etching stop layer 170. However, the present disclosure is not limited thereto. In some embodiments, the side walls of each of the first and second capping patterns 141 and 142 may be in contact with the second etching stop layer 170. Each of the first and second capping patterns 141 and 142 may include, for example, at least one of silicon nitride (SiN), silicon oxynitride (SiON), silicon oxide (SiO₂), silicon carbonitride (SiCN), silicon oxycarbonitride (SiOCN) and/or combinations thereof.

The second interlayer insulating layer 175 may be disposed on the second etching stop layer 170. For example, the second interlayer insulating layer 175 may be in contact with the second etching stop layer 170. The second interlayer insulating layer 175 may be disposed on the side walls of each of the first and second capping patterns 141 and 142. The second interlayer insulating layer 175 may cover the upper source/drain region USD on the first interlayer insulating layer 155. For example, the upper surface of the second interlayer insulating layer 175 may be formed on the same plane as the upper surface of each of the first and second capping patterns 141 and 142. The second interlayer insulating layer 175 may include, for example, but not be limited to, at least one of silicon oxide (SiO₂), silicon nitride (SiN), silicon oxynitride (SiON), a low dielectric constant material, and/or combinations thereof.

The source/drain contact CA may be disposed on the upper source/drain region USD between the first gate electrode G1 and the second gate electrode G2. The source/drain contact CA may penetrate the second interlayer insulating layer 175 and the second etching stop layer 170 in the vertical direction DR3, and extend to the inside of the upper source/drain region USD. For example, the lower surface of the source/drain contact CA may be formed inside the upper source/drain region USD. That is, the lower surface of the source/drain contact CA may be formed to be higher than the lower surface of the upper source/drain region USD. The source/drain contact CA may be electrically connected to the upper source/drain region USD.

Although FIGS. 2 and 4 depict the source/drain contact CA as being formed of a single film, the present disclosure is not limited thereto. For example, in some embodiments, the source/drain contact CA may be formed of a multi-film. As another example, the upper surface of the source/drain contact CA may be formed on the same plane as the upper surface of the second interlayer insulating layer 175. However, the present disclosure is not limited thereto. In some embodiments, the upper surface of the source/drain contact CA may be formed to be higher than the upper surface of the second interlayer insulating layer 175. The source/drain contact CA may include a conductive material.

The silicide layer SL may be disposed between the source/drain contact CA and the upper source/drain region USD. The silicide layer SL may be disposed along an interface between the source/drain contact CA and the upper source/drain region USD. For example, each of the side wall and the lower surface of the silicide layer SL may be in contact with the upper source/drain region USD. As another example, the lower surface of the silicide layer SL may be formed to be higher than the lower surface of the upper source/drain region USD. The silicide layer SL may include, for example, but not be limited to, a metal silicide material.

For example, the upper source/drain region USD may include layers (e.g., a first layer 161, a second 162, and a third layer 163. For example, the first layer 161 may be in contact with each of the first and second plurality of upper nanosheets UNW1 and UNW2. As another example, the first layer 161 may be in contact with each of the first and second gate insulating layers 131 and 132. In some embodiments, the first layer 161 may be in contact with the silicide layer SL disposed on both side walls of the source/drain contact CA in the first horizontal direction DR1. For example, a thickness of the first layer 161 in the vertical direction DR3 may be reduced in a continuous manner (e.g., non-discrete) toward the source/drain contact CA. That is, the thickness of the first layer 161 in the vertical direction DR3 being in contact with the side walls of the first plurality of upper nanosheets UNW1 may be greater than the thickness of the first layer 161 being in contact with the silicide layer SL. In addition, the thickness of the first layer 161 in the vertical direction DR3 being in contact with the side walls of the second plurality of upper nanosheets UNW2 may be greater than the thickness of the first layer 161 being in contact with the silicide layer SL.

For example, the first layer 161 may include, but not be limited to, at least one of silicon (Si), silicon (Si) doped with arsenic (As), or silicon (Si) doped with phosphorus (P). Although FIG. 2 depicts the first layer 161 as being be formed of a single film, the first layer 161 is shown in this manner for convenience of explanation, and the present disclosure is not limited thereto.

For example, the second layer 162 may be disposed below the first layer 161. As another example, at least a part of the source/drain contact CA may overlap the second layer 162 in the first horizontal direction DR1. As another example, at least a part of the second layer 162 may overlap each of the lowermost nanosheet of the first plurality of upper nanosheets UNW1 and the lowermost nanosheet of the second plurality of upper nanosheets UNW2 in the first horizontal direction DR1. In some embodiments, the lower surface of the source/drain contact CA may be formed inside the second layer 162. For example, the second layer 162 may be in contact with the first interlayer insulating layer 155. However, the present disclosure is not limited thereto. In some embodiments, the second etching stop layer 170 may be disposed between the second layer 162 and the first interlayer insulating layer 155. For example, the second layer 162 may be in contact with the silicide layer SL disposed on the side wall and the lower surface of the source/drain contact CA.

For example, the third layer 163 may be disposed above the first layer 161. As another example, the third layer 163 may be spaced apart from the second layer 162 in the vertical direction DR3. As another example, the first layer 161 may separate the second layer 162 and the third layer 163 in the vertical direction DR3. In some embodiments, the source/drain contact CA may overlap the third layer 163 in the first horizontal direction DR1. For example, at least a part of the third layer 163 may overlap each of the uppermost nanosheet of the first plurality of upper nanosheets UNW1 and the uppermost nanosheet of the second plurality of upper nanosheets UNW2 in the first horizontal direction DR1. As another example, the third layer 163 may be in contact with the silicide layer SL disposed on the side wall of the source/drain contact CA. As another example, the thickness of the third layer 163 in the vertical direction DR3 may continuously increase toward the source/drain contact CA.

In some embodiments, the second layer 162 and the third layer 163 may include the same material. For example, each of the second layer 162 and the third layer 163 may include, but not be limited to, silicon (Si) doped with phosphorus (P). For example, density of crystal of the second layer 162 may be the same as density of crystal of the third layer 163. As another example, the density of crystal of each of the second layer 162 and the third layer 163 may be smaller than the density of crystal of the first layer 161. The density of crystal of the second and third layers 162 and 163 may be smaller as a result of each of the second layer 162 and the third layer 163 being formed at a lower temperature than the first layer 161.

In an embodiment, the concentration of the doping material doped in each of the second layer 162 and the third layer 163 may be greater than the concentration of the doping material doped in the first layer 161. As used herein, the concentration of the doping material may refer to an atomic percentage. For example, each of the second layer 162 and the third layer 163 may include the same material as the first layer 161. As another example, each of the first layer 161, the second layer 162, and the third layer 163 may include, but not be limited to, silicon (Si) doped with phosphorus (P). In such a case, the concentration of phosphorus (P) included in each of the second layer 162 and the third layer 163 may be greater than the concentration of phosphorus (P) included in the first layer 161. In some embodiments, each of the second layer 162 and the third layer 163 may include a material different from that of the first layer 161.

The gate contact CB may be disposed above the first gate electrode G1. The gate contact CB penetrates the first capping pattern 141 in the vertical direction DR3, and may be connected to the first gate electrode G1. Although FIG. 3 depicts the gate contact CB as being formed of a single film, the present disclosure is not limited thereto. In some embodiments, the gate contact CB may be formed of a multi-film. For example, the upper surface of the gate contact CB may be formed on the same plane as each of the upper surface of the source/drain contact CA and the upper surface of the second interlayer insulating layer 175, however, the present disclosure is not limited thereto. The gate contact CB may include a conductive material.

The third etching stop layer 180 may be disposed on the upper surfaces of each of the source/drain contact CA, the first and second capping patterns 141 and 142, and the second interlayer insulating layer 175. Although FIGS. 2 to 4 depict the third etching stop layer 180 as being formed of a single film, the present disclosure is not limited thereto. In some embodiments, the third etching stop layer 180 may be formed of a multi-film. The third etching stop layer 180 may include, for example, but not be limited to, at least one of aluminum oxide (Al₂O₃), aluminum nitride (AlN), hafnium oxide (HfO₂), zirconium oxide (ZrO₂), silicon oxide (SiO₂), silicon nitride (SiN), silicon oxynitride (SiON), a low dielectric constant material, and/or combinations thereof. The third interlayer insulating layer 185 may be disposed on the third etching stop layer 180. The third interlayer insulating layer 185 may include, for example, but not be limited to, at least one of silicon oxide (SiO₂), silicon nitride (SiN), silicon oxynitride (SiON), a low dielectric constant material, and/or combinations thereof.

A first via V1 may penetrate the third interlayer insulating layer 185 and the third etching stop layer 180 in the vertical direction DR3, and may be connected to the source/drain contact CA. A second via V2 may penetrate the third interlayer insulating layer 185 and the third etching stop layer 180 in the vertical direction DR3, and may be connected to the gate contact CB. Although each of the first via V1 and the second via V2 is shown to be formed of a single film in FIGS. 2 to 4, the present disclosure is not limited thereto. In some embodiments, each of the first via V1 and the second via V2 may be formed of a multi-film. Each of the first via V1 and the second via V2 may include a conductive material.

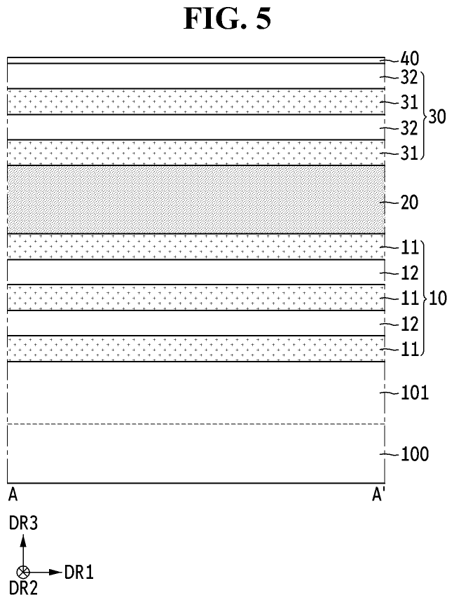

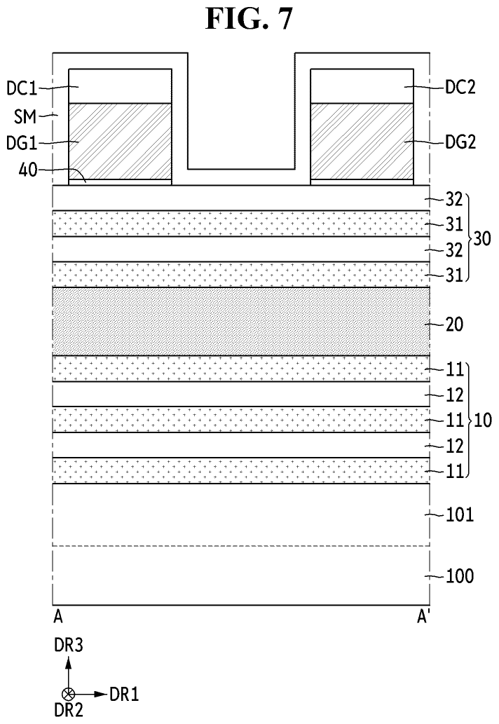

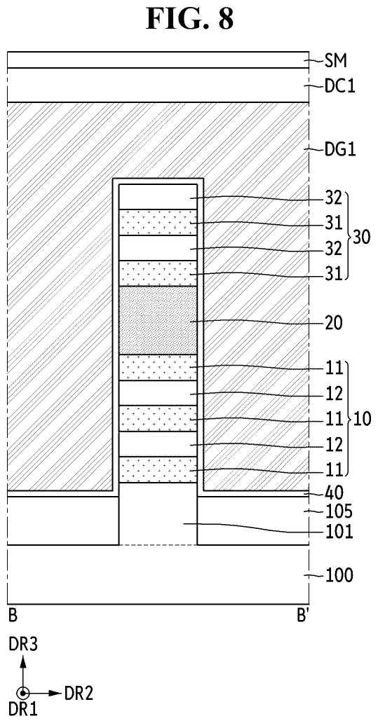

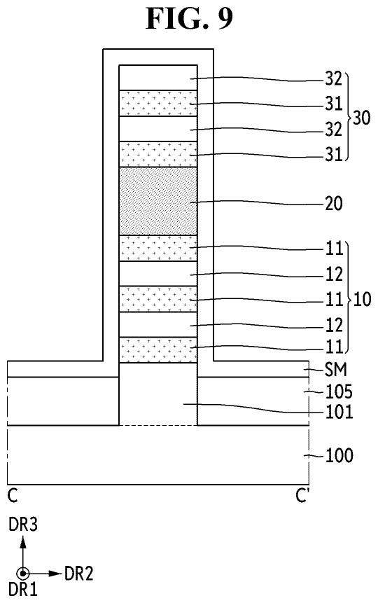

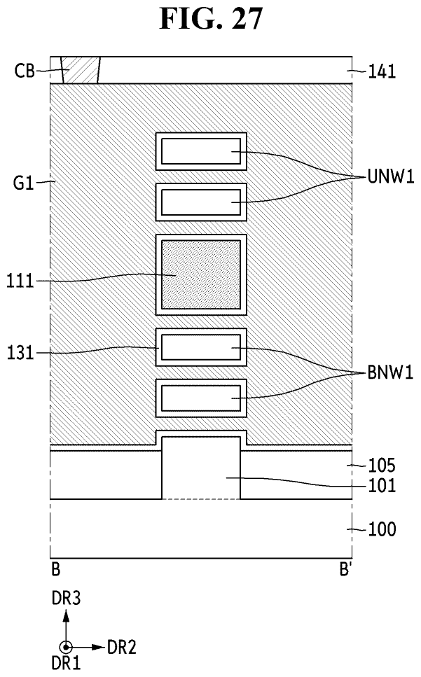

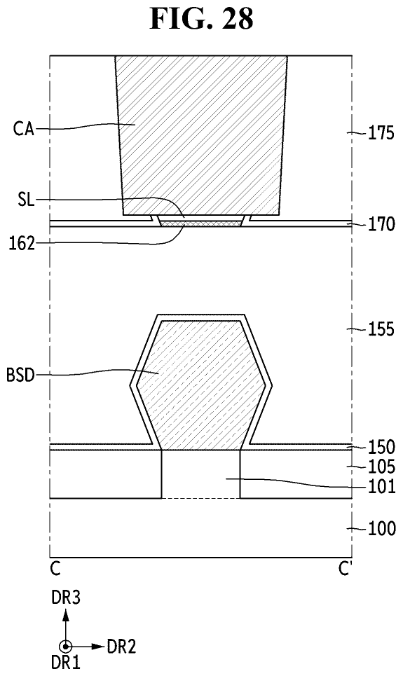

Hereinafter, a method for manufacturing a semiconductor device, according to embodiments of the present disclosure, is described with reference to FIGS. 5 to 28.

FIGS. 5 to 28 are intermediate process diagrams of a method for manufacturing the semiconductor device, according to embodiments of the present disclosure.

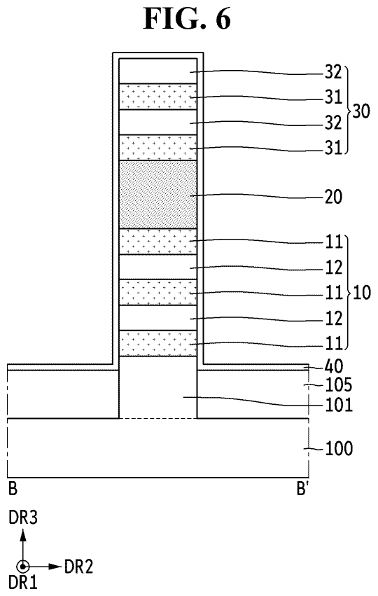

Referring to FIGS. 5 and 6, a first stacked structure 10, a separating material layer 20, and a second stacked structure 30 may be sequentially stacked on the upper surface of the substrate 100. For example, the first stacked structure 10 may be formed on the upper surface of the substrate 100. The first stacked structure 10 may include a first sacrificial layer 11 and a first semiconductor layer 12 that may be alternately stacked on the upper surface of the substrate 100. For example, the first sacrificial layer 11 may be formed on each of the lowermost part and the uppermost part of the first stacked structure 10. However, the present disclosure is not limited thereto. In some embodiments, a first semiconductor layer 12 may be formed on the uppermost part of the first stacked structure 10. For example, the first sacrificial layer 11 may include, but not be limited to, silicon germanium (SiGe). As another example, the first semiconductor layer 12 may include, but not be limited to, silicon (Si).

The separating material layer 20 may be formed on the upper surface of the first stacked structure 10. The separating material layer 20 may include an insulating material. For example, the separating material layer 20 may include, but not be limited to, at least one of silicon nitride (SiN), silicon oxycarbonitride (SiOCN), silicon boron carbonitride (SiBCN), silicon carbonitride (SiCN), silicon oxynitride (SiON), and/or combinations thereof.

The second stacked structure 30 may be formed on the upper surface of the separating material layer 20. The second stacked structure 30 may include a second sacrificial layer 31 and a second semiconductor layer 32 that may be alternately stacked on the upper surface of the separating material layer 20. For example, the second sacrificial layer 31 may be formed at the lowermost part of the second stacked structure 30, and the second semiconductor layer 32 may be formed at the uppermost part of the second stacked structure 30. However, the present disclosure is not limited thereto. In some embodiments, the second semiconductor layer 32 may be formed at the uppermost part of the second stacked structure 30. For example, the second sacrificial layer 31 may include, but not be limited to, silicon germanium (SiGe). As another example, the second semiconductor layer 32 may include, but not be limited to, silicon (Si).

In some embodiments, a part of each of the first stacked structure 10, the separating material layer 20, and the second stacked structure 30 may be etched. While a part of each of the first stacked structure 10, the separating material layer 20, and the second stacked structure 30 is being etched, a part of the substrate 100 may also be etched. The active pattern 101 may be formed below the first stacked structure 10 on the upper surface of the substrate 100 through such an etching process. The active pattern 101 may protrude from the upper surface of the substrate 100 in the vertical direction DR3. The active pattern 101 may extend in the first horizontal direction DR1.

Subsequently, the field insulating layer 105 may be formed on the upper surface of the substrate 100. The field insulating layer 105 may surround the side wall of the active pattern 101. For example, the upper surface of the active pattern 101 may be formed to be higher than the upper surface of the field insulating layer 105. A pad oxide layer 40 may be formed to cover the upper surface of the field insulating layer 105, the side walls of the exposed active pattern 101, the side walls of the first stacked structure 10, the side walls of the separating material layer 20, and the side walls and upper surface of the second stacked structure 30. For example, the pad oxide layer 40 may be formed conformally. The pad oxide layer 40 may include, for example, but not be limited to, silicon oxide (SiO₂).

Referring to FIGS. 6 to 9, first and second dummy gates DG1 and DG2 and first and second dummy capping patterns DC1 and DC2 extending in the second horizontal direction DR2 on the pad oxide layer 40 may be formed on the second stacked structure 30 and the field insulating layer 105. For example, the second dummy gate DG2 may be spaced apart from the first dummy gate DG1 in the first horizontal direction DR1. The first dummy capping pattern DC1 may be disposed on the first dummy gate DG1. The second dummy capping pattern DC2 may be disposed on the second dummy gate DG2. While the first and second dummy gates DG1 and DG2 and the first and second dummy capping patterns DC1 and DC2 are being formed, the remaining pad oxide layer 40 except the portion that overlaps the first and second dummy gates DG1 and DG2 on the substrate 100 in the vertical direction DR3 may be removed.

A spacer material layer SM may be formed to cover the side walls of each of the first and second dummy gates DG1 and DG2, the side walls and upper surfaces of each of the first and second dummy capping patterns DC1 and DC2, the side walls and upper surface of the exposed second stacked structure 30, the side walls of the exposed separating material layer 20, the side walls of the exposed first stacked structure 10, and the upper surface of the field insulating layer 105. For example, the spacer material layer SM may be formed conformally. The spacer material layer SM may include, for example, but not be limited to, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and/or combinations thereof.

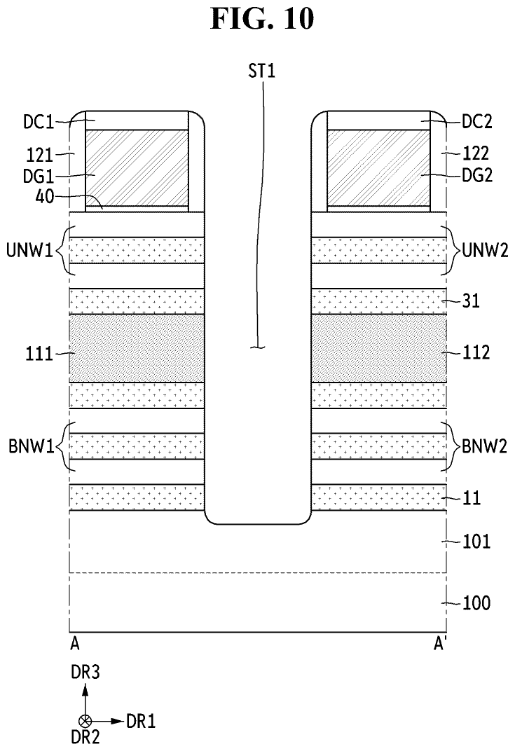

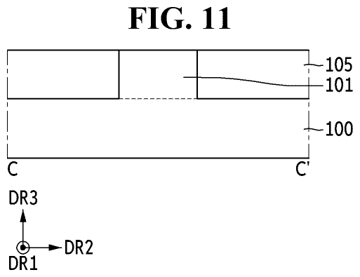

Referring to FIGS. 10 and 11, the first stacked structure 10, the separating material layer 20 and the second stacked structure 30 may be etched by using the first and second dummy gates DG1 and DG2 and the first and second dummy capping patterns DC1 and DC2 as masks, thereby forming a first source/drain trench ST1. For example, the first source/drain trench ST1 may extend to the inside of the active pattern 101. As another example, while the first source/drain trench ST1 is being formed, the spacer material layer SM formed on the upper surface of each of the first and second dummy capping patterns DC1 and DC2 and a part of each of the first and second dummy capping patterns DC1 and DC2 may be etched. The spacer material layer SM that remains on the side walls of each of the first and second dummy capping patterns DC1 and DC2 and the first and second dummy gates DG1 and DG2 may be referred to as first and second gate spacers 121 and 122.

For example, after the first source/drain trench ST1 is formed, each of the first semiconductor layer 12 and the second semiconductor layer 32 that remain below the first dummy gate DG1 may be referred to as a first plurality of lower nanosheets BNW1 and a first plurality of upper nanosheets UNW1. In addition, after the first source/drain trench ST1 is formed, each of the first semiconductor layer 12 and the second semiconductor layer 32 that remain below the second dummy gate DG2 may be referred to as a second plurality of lower nanosheets BNW2 and a second plurality of upper nanosheets UNW2. In addition, after the first source/drain trench ST1 is formed, the separating material layer 20 that remains below the first dummy gate DG1 may be referred to as a first nanosheet separating layer 111, and the separating material layer 20 that remains below the second dummy gate DG2 may be referred to as a second nanosheet separating layer 112.

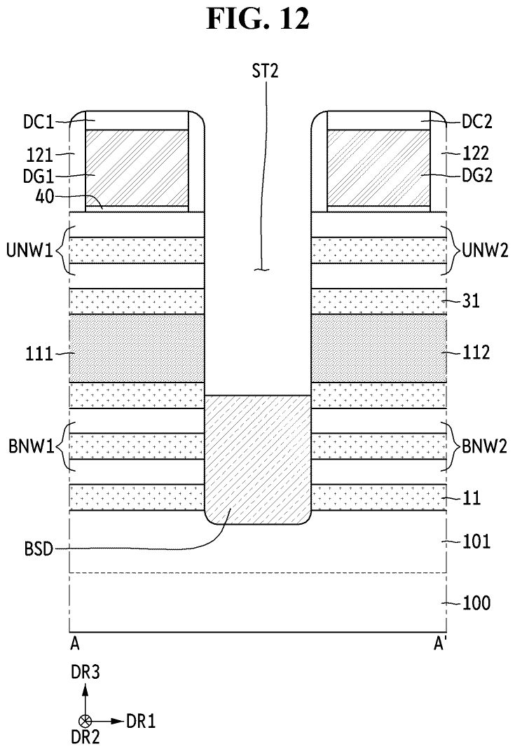

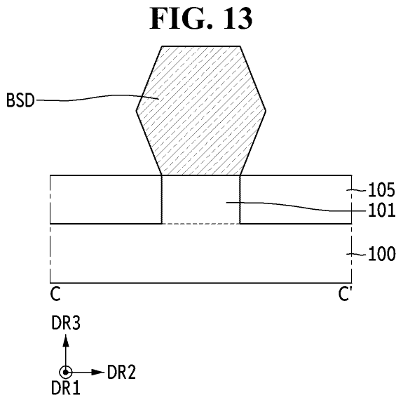

Referring to FIGS. 12 and 13, a lower source/drain region BSD may be formed inside the first source/drain trench ST1. The lower source/drain region BSD may be in contact with the active pattern 101. In addition, the lower source/drain region BSD may be in contact with each of the side walls of the first plurality of lower nanosheets BNW1 in the first horizontal direction DR1 and the side walls of the second plurality of lower nanosheets BNW2 in the first horizontal direction DR1. For example, the upper surface of the lower source/drain region BSD may be formed to be higher than the upper surface of the uppermost nanosheet of the first plurality of lower nanosheets BNW1 and the upper surface of the uppermost nanosheet of the second plurality of lower nanosheets BNW2. As another example, the upper surface of the lower source/drain region BSD may be formed to be lower than the lower surfaces of each of the first and second nanosheet separating layers 111 and 112. However, the present disclosure is not limited thereto. After the lower source/drain region BSD is formed, the region that remains on the upper surface of the lower source/drain region BSD inside the first source/drain trench ST1 may be referred to as a second source/drain trench ST2.

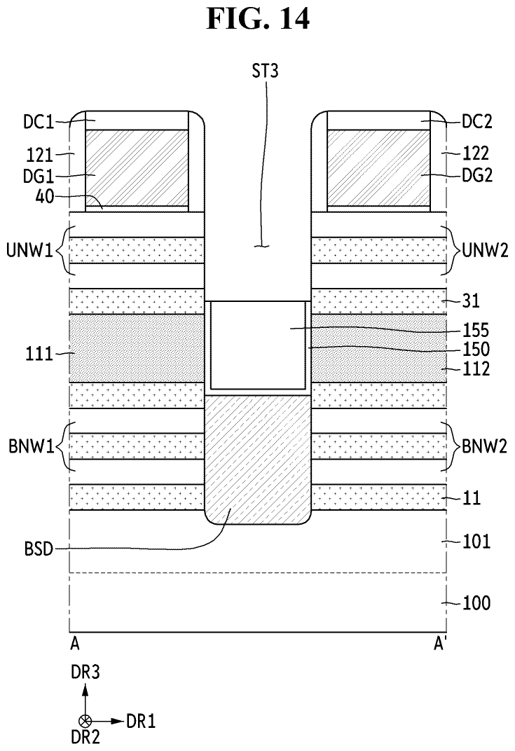

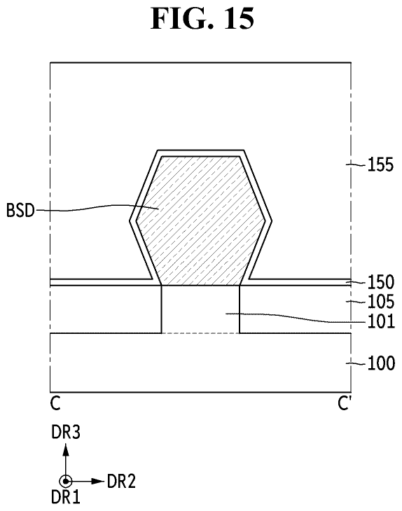

Referring to FIGS. 14 and 15, the first etching stop layer 150 may be formed on the upper surface of the field insulating layer 105, the side walls in the second horizontal direction DR2 and the upper surface of the lower source/drain region BSD. In addition, the first etching stop layer 150 may be formed on the side walls of each of the first and second nanosheet separating layers 111 and 112, the side walls of each of the first and second plurality of upper nanosheets UNW1 and UNW2, the side walls of the second sacrificial layer 31, the side walls of each of the second first and second gate spacers 121 and 122, and the upper surfaces of each of the first and second dummy capping patterns DC1 and DC2. Next, a first interlayer insulating layer 155 may be formed on the first etching stop layer 150. Then, a part of each of the first etching stop layer 150 and the first interlayer insulating layer 155 may be etched.

For example, the upper surfaces of each of the remaining first etching stop layer 150 and the first interlayer insulating layer 155 may be formed to be lower than the lower surface of the lowermost nanosheet of the first plurality of upper nanosheets UNW1 and the lower surface of the lowermost nanosheet of the second plurality of upper nanosheets UNW2. For example, the upper surfaces of each of the remaining first etching stop layer 150 and the first interlayer insulating layer 155 may be formed to be higher than the upper surfaces of each of the first and second nanosheet separating layers 111 and 112. However, the present disclosure is not limited thereto. After each of the first etching stop layer 150 and the first interlayer insulating layer 155 is partially etched, the region that remains on the upper surfaces of each of the first etching stop layer 150 and the first interlayer insulating layer 155 inside the second source/drain trench ST2 may be referred to as a third source/drain trench ST3.

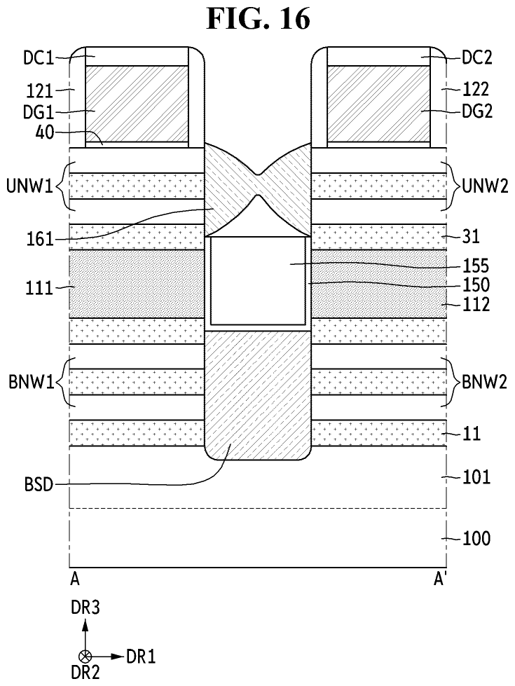

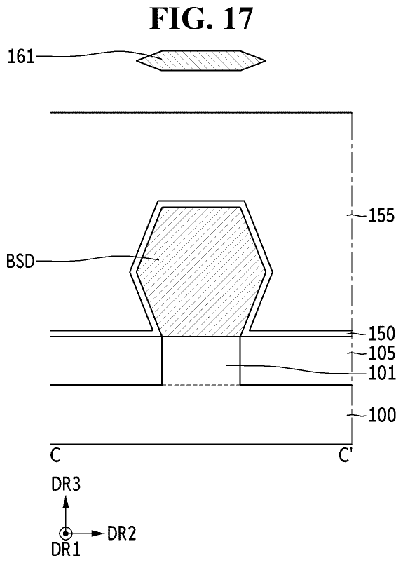

Referring to FIGS. 16 and 17, a first layer 161 may be formed inside the third source/drain trench ST3. For example, the first layer 161 may be formed by an epitaxial growth from the side walls of each of the first and second plurality of upper nanosheets UNW1 and UNW2 in the first horizontal direction DR1. As another example, the thickness of the first layer 161 in the vertical direction DR3 being in contact with the side walls of the first and second plurality of upper nanosheets UNW1 and UNW2 in the first horizontal direction DR1 may be greater than a thickness of a central portion of the first layer 161 in the vertical direction DR3. In some embodiments, the central portion of the first layer 161 may be spaced apart from the first interlayer insulating layer 155 in the vertical direction DR3. For example, in a cross-sectional view taken along the first horizontal direction DR1, the first layer 161 may have a butterfly shape. As another example, the first layer 161 may be formed at a process temperature having a range of about 600° C. to about 700° C.

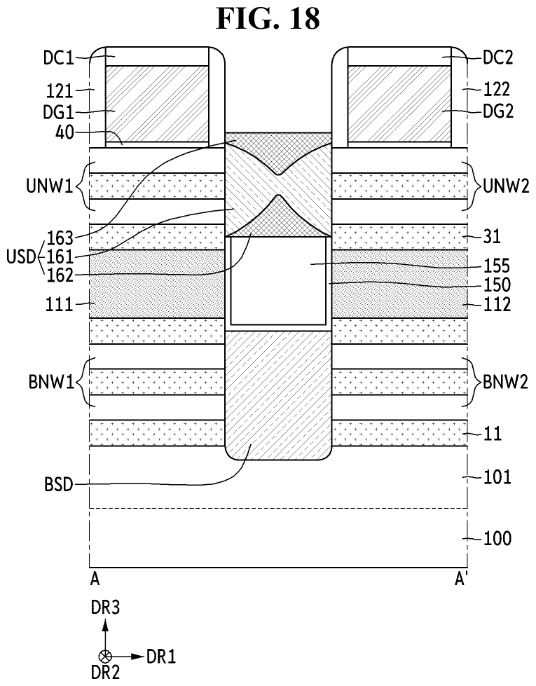

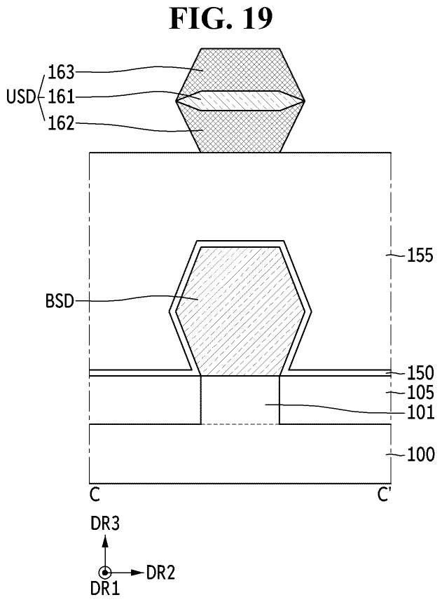

Referring to FIGS. 18 and 19, the second layer 162 may be formed below the first layer 161, and the third layer 163 may be formed above the first layer 161. Thus, the upper source/drain region USD including the first layer 161, the second layer 162, and the third layer 163 may be included between the first plurality of upper nanosheets UNW1 and the second plurality of upper nanosheets UNW2. For example, each of the second layer 162 and the third layer 163 may be formed by the epitaxial growth from the surface of the first layer 161. As another example, each of the second layer 162 and the third layer 163 may be in contact with the first layer 161. In some embodiments, the second layer 162 may be in contact with the first interlayer insulating layer 155. For example, the third layer 163 may be in contact with each of the first and second gate spacers 121 and 122. As another example, the third layer 163 may be spaced apart from the second layer 162 in the vertical direction DR3. In some embodiments, the first layer 161 may separate the second layer 162 and the third layer 163 in the vertical direction DR3. However, the present disclosure is not limited thereto. For example, the second layer 162 and the third layer 163 may be in contact with both side walls of the first layer 161 in the second horizontal direction DR2.

For example, in a cross-sectional view taken along the first horizontal direction DR1, the thickness of the second layer 162 in the vertical direction DR3 may continuously increase from the edge portion of the second layer 162 toward the center of the second layer 162. In addition, in the cross-sectional view taken along the first horizontal direction DR1, the thickness of the third layer 163 in the vertical direction DR3 may continuously increase from the edge portion of the third layer 163 toward the center of the third layer 163. For example, each of the second layer 162 and the third layer 163 may be formed through the same manufacturing process. As another example, each of the second layer 162 and the third layer 163 may be formed at a process temperature having a range of about 400° C. to about 500° C. That is, each of the second layer 162 and the third layer 163 may be formed at a process temperature lower than the process temperature at which the first layer 161 is formed. Therefore, the densities of crystals of each of the second layer 162 and the third layer 163 may be lower than the density of crystal of the third layer 163.

For example, in the cross-sectional view taken along the first horizontal direction DR1 as shown in FIG. 18, each of the maximum thickness of the second layer 162 in the vertical direction DR3 and the maximum thickness of the third layer 163 in the vertical direction DR3 may be greater than the minimum thickness of the first layer 161 in the vertical direction DR3. In some embodiments, in the cross-sectional view taken along the first horizontal direction DR1 shown in FIG. 18, the maximum thickness of the third layer 163 in the vertical direction DR3 may be greater than the maximum thickness of the second layer 162 in the vertical direction DR3. In some embodiments, in the cross-sectional view taken along the first horizontal direction DR1 shown in FIG. 18, the maximum thickness of the third layer 163 in the vertical direction DR3 may be smaller than the maximum thickness of the second layer 162 in the vertical direction DR3. In some embodiments, in the cross-sectional view taken along the first horizontal direction DR1 shown in FIG. 18, the maximum thickness of the third layer 163 in the vertical direction DR3 may be the same as the maximum thickness of the second layer 162 in the vertical direction DR3.

In some embodiments, in the cross-sectional view taken along the first horizontal direction DR1 shown in FIG. 18, the uppermost part of the second layer 162 may be formed to be higher than the upper surface of the lowermost nanosheet of the first plurality of upper nanosheets UNW1. In some embodiments, in the cross-sectional view taken along the first horizontal direction DR1 shown in FIG. 18, the uppermost part of the second layer 162 may be formed to be lower than the upper surface of the lowermost nanosheet of the first plurality of upper nanosheets UNW1. In some embodiments, in the cross-sectional view taken along the first horizontal direction DR1 shown in FIG. 18, the uppermost part of the second layer 162 may be formed at the same height as the upper surface of the lowermost nanosheet of the first plurality of upper nanosheets UNW1.

In some embodiments, in the cross-sectional view taken along the first horizontal direction DR1 shown in FIG. 18, the lowermost part of the third layer 163 may be formed to be lower than the lower surface of the uppermost nanosheet of the first plurality of upper nanosheets UNW1. In some embodiments, in the cross-sectional view taken along the first horizontal direction DR1 shown in FIG. 18, the lowermost part of the third layer 163 may be formed to be higher than the lower surface of the uppermost nanosheet of the first plurality of upper nanosheets UNW1. In some embodiments, in the cross-sectional view taken along the first horizontal direction DR1 shown in FIG. 18, the lowermost part of the third layer 163 may be formed at the same height as the lower surface of the uppermost nanosheet of the first plurality of upper nanosheets UNW1.

For example, in the cross-sectional view taken along the first horizontal direction DR1 shown in FIG. 18, the maximum thickness of the second layer 162 in the vertical direction DR3 may be greater than the thickness of each of the first plurality of upper nanosheets UNW1 in the vertical direction DR3. In addition, in the cross-sectional view taken along the first horizontal direction DR1 shown in FIG. 18, the maximum thickness of the third layer 163 in the vertical direction DR3 may be greater than the thickness of each of the first plurality of upper nanosheets UNW1 in the vertical direction DR3.

In some embodiments, in the cross-sectional view taken along the first horizontal direction DR1 shown in FIG. 18, the minimum thickness of the first layer 161 in the vertical direction DR3 may be greater than the thickness of each nanosheet of the first plurality of upper nanosheets UNW1 in the vertical direction DR3. In some embodiments, in the cross-sectional view taken along the first horizontal direction DR1 shown in FIG. 18, the minimum thickness of the first layer 161 in the vertical direction DR3 may be smaller than the thickness of each nanosheet of the first plurality of upper nanosheets UNW1 in the vertical direction DR3. In some embodiments, in the cross-sectional view taken along the first horizontal direction DR1 shown in FIG. 18, the minimum thickness of the first layer 161 in the vertical direction DR3 may be the same as the thicknesses of each nanosheet of the first plurality of upper nanosheets UNW1 in the vertical direction DR3.

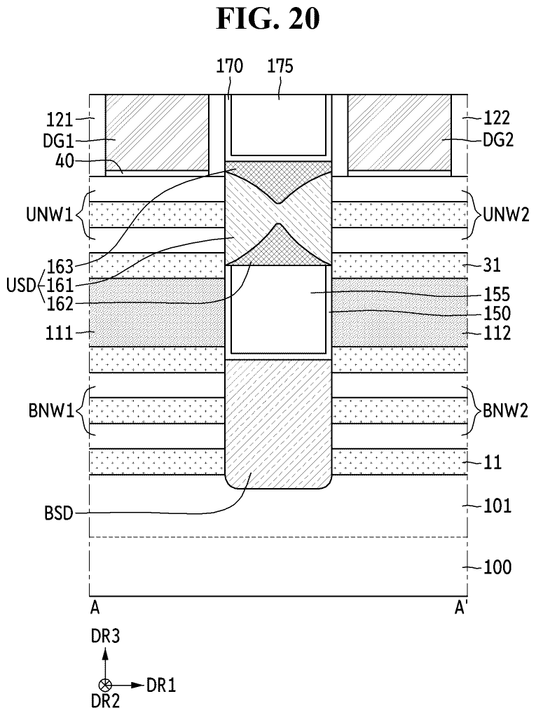

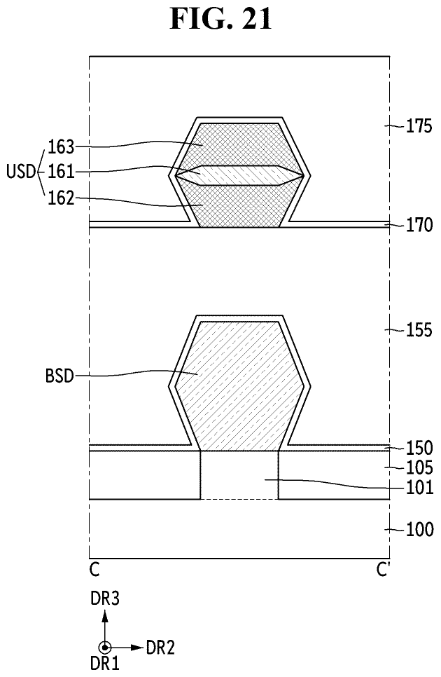

Referring to FIGS. 20 and 21, the second etching stop layer 170 may be formed on the upper surface of the first interlayer insulating layer 155, the side walls in the second horizontal direction DR2 and the upper surface of the upper source/drain region USD, and the side walls of each of the first and second gate spacers 121 and 122. For example, the second etching stop layer 170 may be conformally formed. The second interlayer insulating layer 175 is formed on the second etching stop layer 170. The planarization process may be performed to expose the upper surfaces of each of the first and second dummy gates DG1 and DG2.

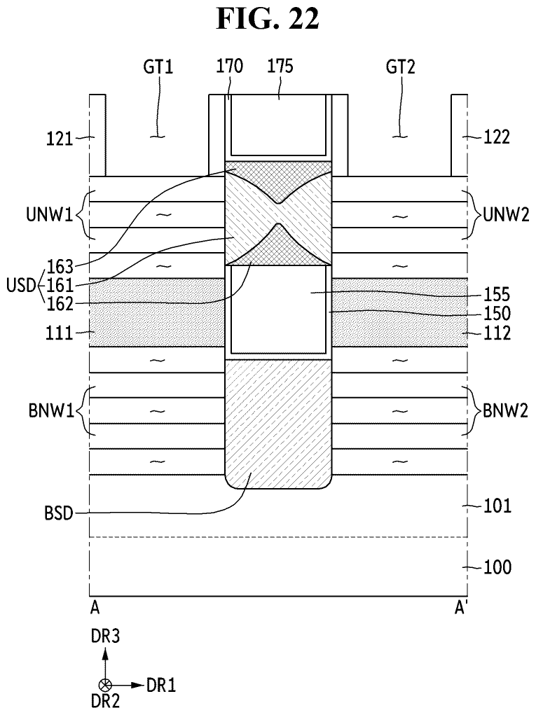

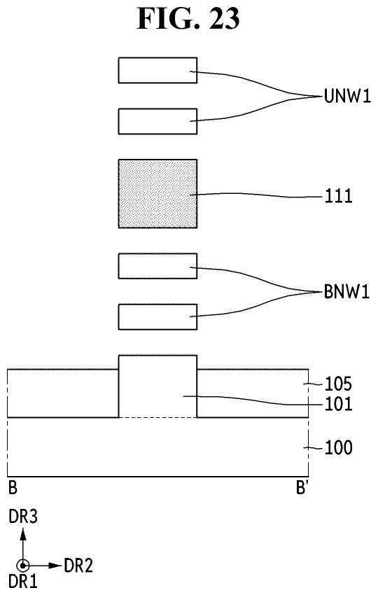

Referring to FIGS. 22 and 23, each of the first and second dummy gates DG1 and DG2, the pad oxide layer 40, the first sacrificial layer 11, and the second sacrificial layer 31 may be etched. The etched portions of each of the first dummy gate DG1, the pad oxide layer 40, the first sacrificial layer 11, and the second sacrificial layer 31 may be referred to as a first gate trench GT1. In addition, the etched portions of each of the second dummy gate DG2, the pad oxide layer 40, the first sacrificial layer 11, and the second sacrificial layer 31 may be referred to as a second gate trench GT2.

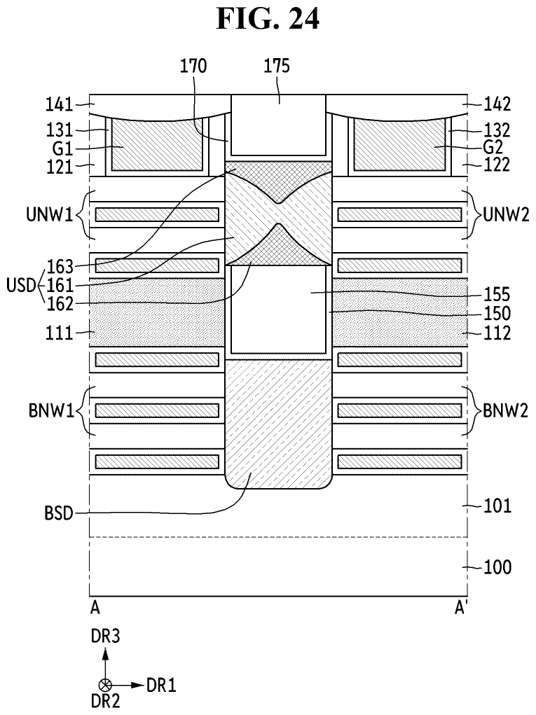

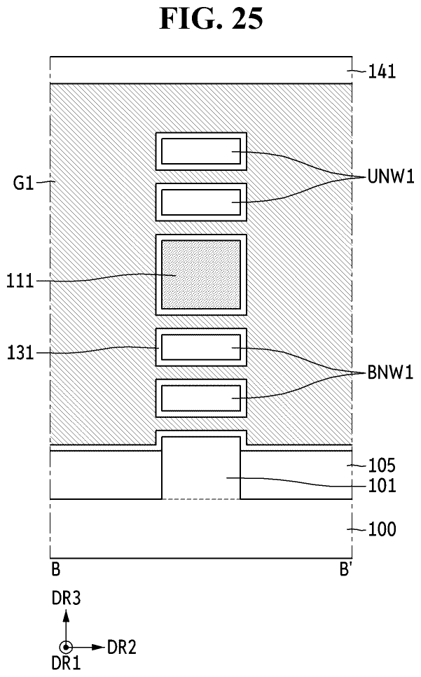

Referring to FIGS. 24 and 25, the first gate insulating layer 131, the first gate electrode G1, and the first capping pattern 141 may be sequentially formed inside the first gate trench GT1. In addition, the second gate insulating layer 132, the second gate electrode G2, and the second capping pattern 142 may be sequentially formed inside the second gate trench GT2. For example, the first gate electrode G1 may surround each of the first plurality of lower nanosheets BNW1, the first nanosheet separating layer 111, and the first plurality of upper nanosheets UNW1. The second gate electrode G2 may surround each of the second plurality of lower nanosheets BNW2, the second nanosheet separating layer 112, and the second plurality of upper nanosheets UNW2.

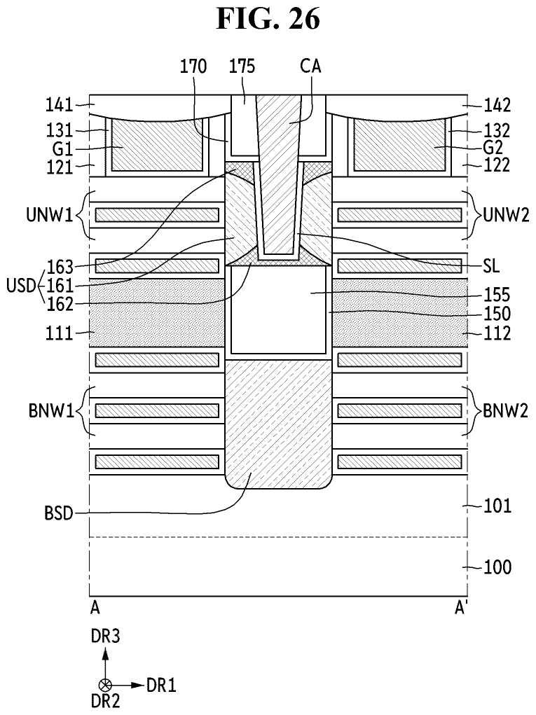

Referring to FIGS. 26 to 28, a source/drain contact CA that penetrates the second interlayer insulating layer 175 and the second etching stop layer 170 in the vertical direction DR3 and extends into the upper source/drain region USD may be formed between the first gate electrode G1 and the second gate electrode G2. For example, the source/drain contact CA may penetrate the third layer 163 and the first layer 161 and extend to the inside of the second layer 162. That is, the lower surface of the source/drain contact CA may be formed inside the second layer 162. For example, the upper surface of the source/drain contact CA may be formed on the same plane as the upper surface of the second interlayer insulating layer 175.

In addition, a silicide layer SL may be formed between the upper source/drain region USD and the source/drain contact CA. For example, side walls of the silicide layer SL may be in contact with each of the first to third layers 161 to 163. A lower surface of the silicide layer SL may be in contact with the second layer 162. In addition, a gate contact CB that penetrates the first capping pattern 141 in the vertical direction DR3 and is connected to the first gate electrode G1 may be formed.

Referring to FIGS. 2 to 4, the third etching stop layer 180 and the third interlayer insulating layer 185 may be sequentially formed on the upper surfaces of each of the first and second capping patterns 141 and 142, the second interlayer insulating layer 175, the source/drain contact CA, and the gate contact CB. A first via V1 that penetrates the third etching stop layer 180 and the third interlayer insulating layer 185 in the vertical direction DR3 and is connected to the source/drain contact CA may be formed. In addition, a second via V2 that penetrates the third etching stop layer 180 and the third interlayer insulating layer 185 in the vertical direction DR3 and is connected to the gate contact CB may be formed. The semiconductor device shown in FIGS. 2 to 4 may be manufactured through such a manufacturing process.

In the semiconductor device having a structure in which a plurality of upper nanosheets are stacked on a plurality of lower nanosheets, the upper source/drain region disposed on the side walls of the plurality of upper nanosheets may be formed by the epitaxial growth only from the side walls of the plurality of upper nanosheets. In such a case, the upper source/drain region is formed so that the thickness of the central portion in the vertical direction DR3 is relatively smaller than the thickness of the edge portion in the vertical direction DR3, and the reliability of the electrical connection between the source/drain contact and the upper source/drain region may be degraded, accordingly.

In the method for manufacturing the semiconductor device, according to embodiments of the present disclosure, when forming the upper source/drain region USD, after the first layer 161 is formed in a relatively high temperature process, the second layer 162 and the third layer 163 may be formed below and above the first layer 161 in a relatively low temperature process. The concentration of the doping material contained in each of the second layer 162 and the third layer 163 formed in the relatively low temperature process may be greater than the concentration of the doping material contained in the first layer 161 formed in the relatively high temperature process. Furthermore, the density of crystal of each of the second layer 162 and the third layer 163 formed in the relatively low temperature process may be smaller than the density of crystal of the first layer 161 formed in the relatively high temperature process. Therefore, in the method for manufacturing the semiconductor device, according to embodiments of the present disclosure, because the activity of the doping material doped in each of the second layer 162 and the third layer 163 is formed to be greater than the activity of the material doped in the first layer 161, the reliability of the electrical connection between the source/drain contact CA and the upper source/drain region USD may be improved.

In addition, in the method for manufacturing the semiconductor device, according to embodiments of the present disclosure, a region between the source/drain contact CA and the upper source/drain region USD may be increased, by forming the second layer 162 and the third layer 163 below and above the first layer 161. Therefore, the method for manufacturing the semiconductor device, according to embodiments of the present disclosure, may improve the reliability of the electrical connection between the source/drain contact CA and the upper source/drain region USD, when compared to related semiconductor devices.

In the semiconductor device, according to embodiments of the present disclosure, manufactured by the above-mentioned method for manufacturing the semiconductor device, the upper source/drain region USD may include the first layer 161, the second layer 162 disposed below the first layer 161, and the third layer 163 disposed above the first layer 161. The third layer 163 may be spaced apart from the second layer 162 in the vertical direction DR3. The second layer 162 and the third layer 163 may include the same material, and the density of crystal of the second layer 162 may be the same as the density of crystal of the third layer 163. The density of crystal of each of the second layer 162 and the third layer 163 may be smaller than the density of crystal of the first layer 161. The concentration of the doping material included in each of the second layer 162 and the third layer 163 may be greater than the concentration of the doping material included in the first layer 161.

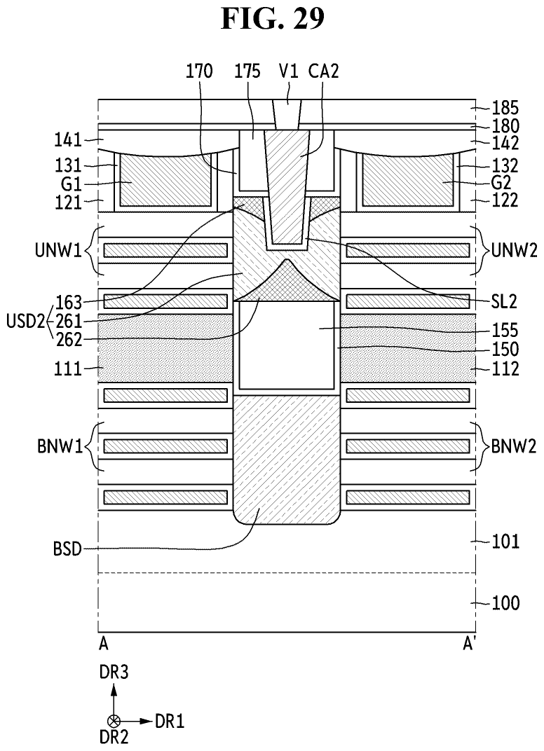

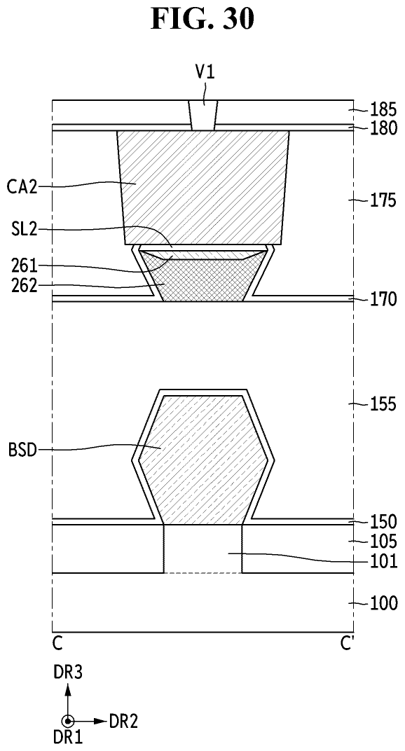

Hereinafter, a semiconductor device, according to embodiments of the present disclosure, is described with reference to FIGS. 29 and 30. The semiconductor device of FIGS. 29 and 30 may include and/or may be similar in many respects to the semiconductor device described above with reference to FIGS. 1 to 4, and may include additional features not mentioned above. Consequently, repeated descriptions of the semiconductor device described above with reference to FIGS. 1 to 4 may be omitted for the sake of brevity.

FIGS. 29 and 30 are cross-sectional views of a semiconductor device, according to embodiments of the present disclosure.

Referring to FIGS. 29 and 30, in the semiconductor device, according to embodiments of the present disclosure, the source/drain contact CA2 may extend to the inside of the first layer 261.

For example, the upper source/drain region USD2 may include the first layer 261, the second layer 262 disposed below the first layer 261, and the third layer 163 disposed above the first layer 261. As another example, the lower surface of the source/drain contact CA2 may be formed inside the first layer 261. That is, the lower surface of the source/drain contact CA2 may be spaced apart from the second layer 262 in the vertical direction DR3. For example, the thickness of the second layer 262 in the vertical direction DR3 may continuously increase toward the source/drain contact CA2. As another example, the silicide layer SL2 may be disposed between the source/drain contact CA2 and the first layer 261. The silicide layer SL2 may also be disposed between the source/drain contact CA2 and the third layer 163. For example, the silicide layer SL2 may be spaced apart from the second layer 262 in the vertical direction DR3.

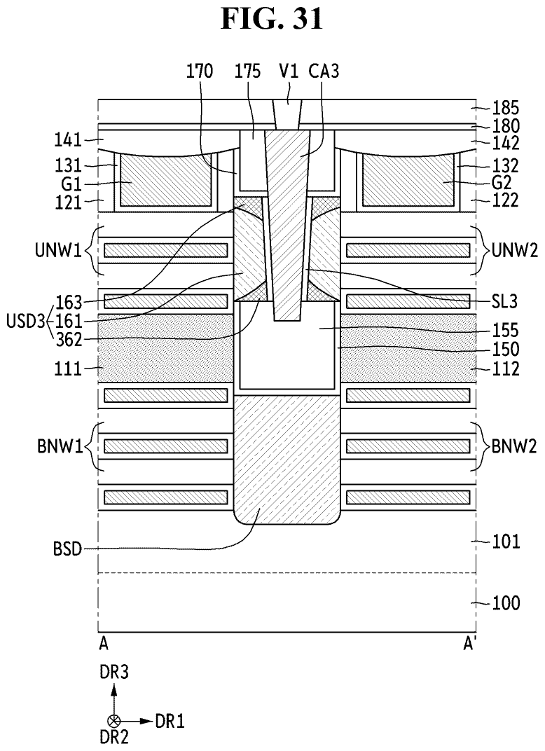

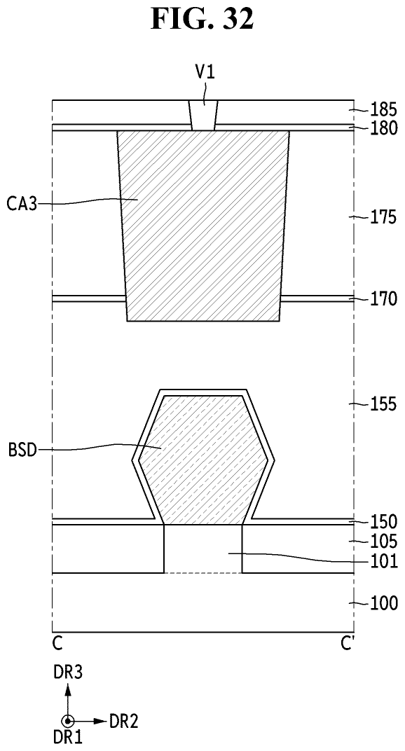

Hereinafter, a semiconductor device, according to embodiments of the present disclosure, is described with reference to FIGS. 31 and 32. The semiconductor device of FIGS. 31 and 32 may include and/or may be similar in many respects to the semiconductor device described above with reference to FIGS. 1 to 4, and may include additional features not mentioned above. Consequently, repeated descriptions of the semiconductor device described above with reference to FIGS. 1 to 4 may be omitted for the sake of brevity.

FIGS. 31 and 32 are cross-sectional views of a semiconductor device, according to embodiments of the present disclosure.

Referring to FIGS. 31 and 32, in the semiconductor device, according to embodiments of the present disclosure, the source/drain contact CA3 may extend to the inside of the first interlayer insulating layer 155.

For example, the upper source/drain region USD3 may include the first layer 161, the second layer 362 disposed below the first layer 161, and the third layer 163 disposed above the first layer 161. As another example, the source/drain contact CA3 penetrates each of the third layer 163, the first layer 161, and the second layer 362 in the vertical direction DR3, and may extend to the inside of the first interlayer insulating layer 155. That is, the lower surface of the source/drain contact CA3 may be formed to be lower than the lower surface of the second layer 362. The lower surface of the source/drain contact CA3 may be formed inside the first interlayer insulating layer 155. For example, the thickness of the second layer 362 in the vertical direction DR3 may continuously increase toward the source/drain contact CA3. As another example, the silicide layer SL3 may be disposed between the source/drain contact CA3, the first layer 161, the second layer 362, and the third layer 163. As another example, the silicide layer SL3 may extend from the lower surface of the second layer 362 to the upper surface of the third layer 163 along both side walls of the source/drain contact CA3 in the first horizontal direction DR1.

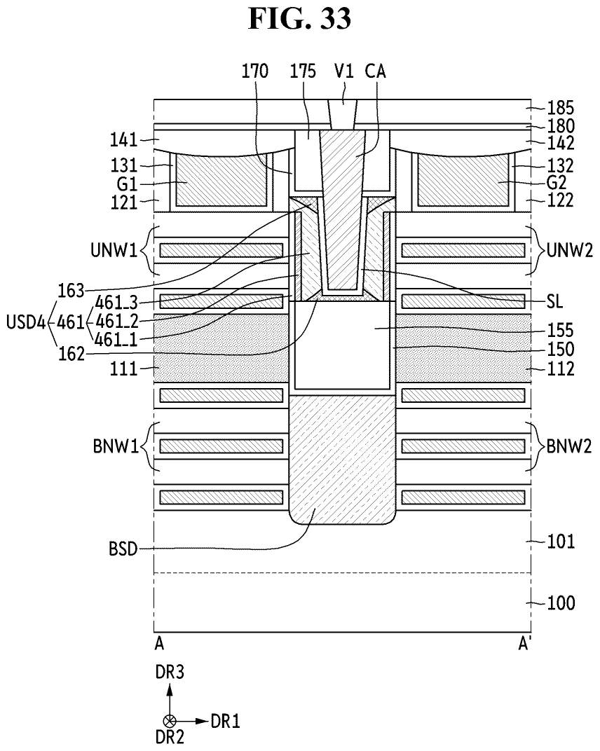

Hereinafter, a semiconductor device, according to embodiments of the present disclosure, is described with reference to FIG. 33. The semiconductor device of FIG. 33 may include and/or may be similar in many respects to the semiconductor device described above with reference to FIGS. 1 to 4, and may include additional features not mentioned above. Consequently, repeated descriptions of the semiconductor device described above with reference to FIGS. 1 to 4 may be omitted for the sake of brevity.

FIG. 33 is a cross-sectional view of a semiconductor device, according to embodiments of the present disclosure.

Referring to FIG. 33, in the semiconductor device, according to embodiments of the present disclosure, the upper source/drain region USD4 may include a first layer 461, a second layer 162 disposed below the first layer 461, and a third layer 163 disposed above the first layer 461.

For example, the first layer 461 may include a first sublayer 461_1, a second sublayer 461_2, and a third sublayer 461_3. As another example, the first sublayer 461_1 may be in contact with the side walls of each of the first and second plurality of upper nanosheets UNW1 and UNW2 in the first horizontal direction DR1. In some embodiments, the first sublayer 461_1 may be in contact with each of the first and second gate insulating layers 131 and 132. For example, the third sublayer 461_3 may be in contact with the silicide layer SL. As another example, the second sublayer 461_2 may be disposed between the first sublayer 461_1 and the third sublayer 461_3. That is, the second sublayer 461_2 may be disposed along an interface between the first sublayer 461_1 and the third sublayer 461_3. The second sublayer 461_2 may be in contact with each of the first sublayer 461_1 and the third sublayer 461_3.

For example, in the cross-sectional view taken along the first horizontal direction DR1 shown in FIG. 33, the third sublayer 461_3 may be in contact with each of the upper surface of the first sublayer 461_1 and the upper surface of the second sublayer 461_2. However, the present disclosure is not limited thereto. For example, the first sublayer 461_1 may include, but not be limited to, silicon (Si). For example, the second sub-layer 461_2 may include silicon (Si) doped with arsenic (As). As another example, the third sub-layer 461_3 may include, but not be limited to, silicon (Si) doped with phosphorus (P). However, the present disclosure is not limited thereto.

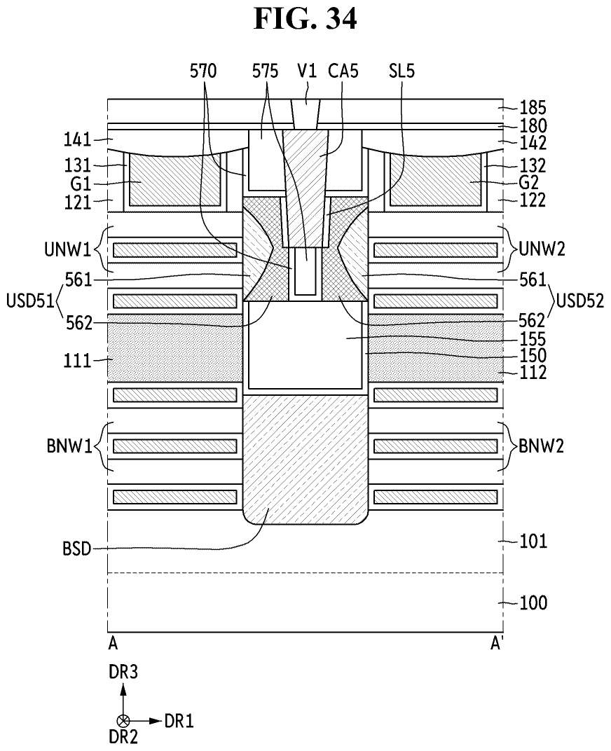

Hereinafter, a semiconductor device, according to embodiments of the present disclosure, is described with reference to FIG. 34. The semiconductor device of FIG. 34 may include and/or may be similar in many respects to the semiconductor device described above with reference to FIGS. 1 to 4, and may include additional features not mentioned above. Consequently, repeated descriptions of the semiconductor device described above with reference to FIGS. 1 to 4 may be omitted for the sake of brevity.

FIG. 34 is a cross-sectional view of a semiconductor device, according to embodiments of the present disclosure.

Referring to FIG. 34, in the semiconductor device, according to embodiments of the present disclosure, the first upper source/drain region USD51 being in contact with the first plurality of upper nanosheets UNW1 may be spaced apart from the second upper source/drain region USD52 being in contact with the second plurality of upper nanosheets UNW2 in the first horizontal direction DR1.

For example, each of the first and second upper source/drain regions USD51 and USD52 may include a first layer 561 and a second layer 562. For example, the first layer 561 of the first upper source/drain region USD51 may be in contact with each of the side walls of the first plurality of upper nanosheets UNW1 in the first horizontal direction DR1 and the first gate insulating layer 131. As another example, the first layer 561 of the second upper source/drain region USD52 may be in contact with each of the side wall of the second plurality of upper nanosheets UNW2 in the first horizontal direction DR1 and the second gate insulating layer 132.

For example, the second layer 562 of the first upper source/drain region USD51 may be disposed on the side wall of the first layer 561 of the first upper source/drain region USD51 in the first horizontal direction DR1. The second layer 562 of the first upper source/drain region USD51 may be in contact with the side wall of the first layer 561 of the first upper source/drain region USD51 in the first horizontal direction DR1. For example, the second layer 562 of the second upper source/drain region USD52 may be disposed on the side wall of the first layer 561 of the second upper source/drain region USD52 in the first horizontal direction DR1. The second layer 562 of the second upper source/drain region USD52 may be in contact with the side wall of the first layer 561 of the second upper source/drain region USD52 in the first horizontal direction DR1. For example, the second layer 562 of the second upper source/drain region USD52 may be spaced apart from the second layer 562 of the first upper source/drain region USD51 in the first horizontal direction DR1.

For example, at least a part of the source/drain contact CA5 may be disposed between the first upper source/drain region USD51 and the second upper source/drain region USD52. As another example, the lower surface of the source/drain contact CA5 may be formed to be higher than the lower surface of the second layer 562. As another example, the source/drain contact CA5 may be electrically connected to each of the first upper source/drain region USD51 and the second upper source/drain region USD52. The silicide layer SL5 may be disposed between the source/drain contact CA5 and the second layer 562 of the first upper source/drain region USD51. The silicide layer SL5 may also be disposed between the source/drain contact CA5 and the second layer 562 of the second upper source/drain region USD52. For example, the silicide layer SL5 may be in contact with each of the second layer 562 of the first upper source/drain region USD51 and the second layer 562 of the second upper source/drain region USD51.

For example, at least a part of the second interlayer insulating layer 575 may be disposed between the first upper source/drain region USD51 and the second upper source/drain region USD52. As another example, the lower surface of the source/drain contact CA5 may be in contact with the second interlayer insulating layer 575 between the first upper source/drain region USD51 and the second upper source/drain region USD52. In some embodiments, the second etching stop layer 570 may be disposed between the side walls of each of the first and second upper source/drain regions USD51 and USD52 in the first horizontal direction DR1 and the second interlayer insulating layer 575. For example, the second etching stop layer 570 may also be disposed between the first interlayer insulating layer 155 and the second interlayer insulating layer 575.

Although the embodiments of the present disclosure have been described above with reference to the accompanying drawings, the present disclosure is not limited to the above embodiments, and may be fabricated in various different forms. Those skilled in the art are to appreciate that the present disclosure may be embodied in other specific forms without changing the technical spirit or essential features of the present disclosure. Accordingly, the above-described embodiments should be understood in all respects as illustrative and not restrictive.

What is claimed is:

1. A semiconductor device comprising:
a substrate;
an active pattern extending in a first horizontal direction on the substrate;
a first plurality of upper nanosheets stacked on the active pattern and spaced apart from each other in a vertical direction;
a second plurality of upper nanosheets stacked on the active pattern and spaced apart from each other in the vertical direction, the second plurality of upper nanosheets being spaced apart from the first plurality of upper nanosheets in the first horizontal direction;
a first gate electrode extending in a second horizontal direction different from the first horizontal direction on the active pattern, the first gate electrode at least partially surrounding the first plurality of upper nanosheets;
a second gate electrode extending in the second horizontal direction on the active pattern, the second gate electrode being spaced apart from the first gate electrode in the first horizontal direction, the second gate electrode at least partially surrounding the second plurality of upper nanosheets;
an upper source/drain region between the first plurality of upper nanosheets and the second plurality of upper nanosheets; and
a source/drain contact extending inside of the upper source/drain region and electrically coupled with the upper source/drain region,
wherein the upper source/drain region comprises:
a first layer in contact with side walls of each of the first plurality of upper nanosheets and the second plurality of upper nanosheets in the first horizontal direction;
a second layer below the first layer; and
a third layer above the first layer and comprising a same material as a material of the second layer.

2. The semiconductor device of claim 1, wherein a thickness of the first layer in the vertical direction decreases toward the source/drain contact.

3. The semiconductor device of claim 1, wherein the third layer is spaced apart from the second layer in the vertical direction.

4. The semiconductor device of claim 1, wherein the second layer at least partially overlaps a lowermost nanosheet of the first plurality of upper nanosheets in the first horizontal direction, and
wherein the third layer at least partially overlaps an uppermost nanosheet of the first plurality of upper nanosheets in the first horizontal direction.

5. The semiconductor device of claim 1, further comprising:
a silicide layer between the upper source/drain region and the source/drain contact, the silicide layer being in contact with each of the first layer and the third layer.

6. The semiconductor device of claim 5, wherein the silicide layer is in contact with the second layer.

7. The semiconductor device of claim 5, wherein the silicide layer extends from a lower surface of the second layer to an upper surface of the third layer.

8. The semiconductor device of claim 1, further comprising:
a first plurality of lower nanosheets between the active pattern and the first plurality of upper nanosheets;
a second plurality of lower nanosheets between the active pattern and the second plurality of upper nanosheets; and
a lower source/drain region between the first plurality of lower nanosheets and the second plurality of lower nanosheets, the lower source/drain region being spaced apart from the upper source/drain region in the vertical direction.

9. The semiconductor device of claim 8, further comprising:
a first nanosheet separating layer between the first plurality of lower nanosheets and the first plurality of upper nanosheets; and
a second nanosheet separating layer between the second plurality of lower nanosheets and the second plurality of upper nanosheets,
wherein the first gate electrode at least partially surrounds the first plurality of lower nanosheets and the first nanosheet separating layer, and
wherein the second gate electrode at least partially surrounds the second plurality of lower nanosheets and the second nanosheet separating layer.

10. The semiconductor device of claim 1, wherein a second crystal density of the second layer is smaller than a first crystal density of the first layer, and
wherein a third crystal density of the third layer is smaller than the first crystal density of the first layer.

11. The semiconductor device of claim 1, wherein a lower surface of the source/drain contact is at least partially inside the second layer.

12. The semiconductor device of claim 1, wherein a lower surface of the source/drain contact is at least partially inside the first layer.

13. A semiconductor device, comprising:
a substrate;
an active pattern extending in a first horizontal direction on the substrate;
a plurality of lower nanosheets stacked on the active pattern and spaced apart from each other in a vertical direction;
a nanosheet separating layer on the plurality of lower nanosheets;
a plurality of upper nanosheets on the nanosheet separating layer;
a gate electrode extending in a second horizontal direction different from the first horizontal direction on the active pattern, the gate electrode at least partially surrounding each of the plurality of lower nanosheets, the nanosheet separating layer, and the plurality of upper nanosheets;
a lower source/drain region on a side of the plurality of lower nanosheets;
an upper source/drain region on a side of the plurality of upper nanosheets, the upper source/drain region at least partially overlapping the lower source/drain region in the vertical direction; and
a source/drain contact extending inside of the upper source/drain region and electrically coupled with the upper source/drain region,
wherein the upper source/drain region comprises:
a first layer in contact with side walls of the plurality of upper nanosheets in the first horizontal direction, a thickness of the first layer in the vertical direction decreasing toward the source/drain contact;
a second layer below the first layer; and
a third layer above the first layer and comprising a third material equal to a second material of the second layer.

14. The semiconductor device of claim 13, wherein a thickness of the second layer in the vertical direction increases toward the source/drain contact, and
wherein a thickness of the third layer in the vertical direction increases toward the source/drain contact.

15. The semiconductor device of claim 13, further comprising:
a silicide layer between the upper source/drain region and the source/drain contact, the silicide layer being in contact with each of the first layer and the third layer.

16. The semiconductor device of claim 15, wherein the silicide layer is in contact with the second layer.

17. The semiconductor device of claim 13, wherein a crystal density of the second layer is equal to a crystal density of the third layer.

18. The semiconductor device of claim 13, wherein the second material of the second layer differs from a first material of the first layer, and
wherein the third material of the third layer differs from the first material of the first layer.

19. The semiconductor device of claim 13, wherein a lower surface of the source/drain contact is lower than a lower surface of the second layer.

20. A semiconductor device, comprising:
a substrate;
an active pattern extending in a first horizontal direction on the substrate;
a first plurality of lower nanosheets stacked on the active pattern and spaced apart from each other in a vertical direction;
a second plurality of lower nanosheets stacked on the active pattern and spaced apart from each other in the vertical direction, the second plurality of lower nanosheets being spaced apart from the first plurality of lower nanosheets in the first horizontal direction;
a first nanosheet separating layer on the first plurality of lower nanosheets;
a second nanosheet separating layer on the second plurality of lower nanosheets, the second nanosheet separating layer being spaced apart from the first nanosheet separating layer in the first horizontal direction;
a first plurality of upper nanosheets stacked on the first nanosheet separating layer and spaced apart from each other in the vertical direction;
a second plurality of upper nanosheets stacked on the second nanosheet separating layer to be spaced apart from each other in the vertical direction, the second plurality of upper nanosheets being spaced apart from the first plurality of upper nanosheets in the first horizontal direction;
a first gate electrode extending in a second horizontal direction different from the first horizontal direction on the active pattern, the first gate electrode at least partially surrounding each of the first plurality of lower nanosheets, the first nanosheet separating layer, and the first plurality of upper nanosheets;
a second gate electrode extending in the second horizontal direction on the active pattern, the second gate electrode spaced apart from the first gate electrode in the first horizontal direction, the second gate electrode at least partially surrounding each of the second plurality of lower nanosheets, the second nanosheet separating layer, and the second plurality of upper nanosheets;
a lower source/drain region between the first plurality of lower nanosheets and the second plurality of lower nanosheets;
an upper source/drain region between the first plurality of upper nanosheets and the second plurality of upper nanosheets, the upper source/drain region at least partially overlapping the lower source/drain region in the vertical direction; and
a source/drain contact extending inside of the upper source/drain region and electrically coupled with the upper source/drain region,
wherein the upper source/drain region comprises:
a first layer in contact with side walls of the first plurality of upper nanosheets and the second plurality of upper nanosheets in the first horizontal direction, a thickness of the first layer in the vertical direction decreasing toward the source/drain contact;
a second layer below the first layer; and
a third layer above the first layer and comprising a same material as a material of the second layer,
wherein a second crystal density of the second layer is smaller than a first crystal density of the first layer,
wherein a third crystal density of the third layer is smaller than the first crystal density of the first layer, and
wherein a lower surface of the source/drain contact is inside the second layer.
